(19) United States
(12) Patent Application Publication
(10) Pub. No.: US 2003/0058697 A1
(43) Pub. Date: Mar. 27, 2003

(54) Programmable molecular device

(76) Inventors: James M. Tour, Bellaire, TX (US); Bill Van Zandt, Houston, TX (US); Christopher Husband, Houston, TX (US); Summer Husband, Houston, TX (US)

Correspondence Address: CONLEY ROSE & TAYON, P.C., P. O. BOX 3267, HOUSTON, TX, 77253-3267, US

(21) Appl. No.: 09/912,923

(22) Filed: Jul. 25, 2001

Related U.S. Application Data
(63) Continuation-in-part of application No. 09/488,339, filed on Jan. 20, 2000, now Pat. No. 6,430,511.
(63) Continuation-in-part of application No. 08/595,130, filed on Feb. 1, 1996, now Pat. No. 6,320,200.
(63) Continuation-in-part of application No. 08/261,867, filed on Jun. 16, 1994, now abandoned.
(63) Continuation-in-part of application No. 07/891,605, filed on Jun. 1, 1992, now abandoned.
(63) Continuation-in-part of application No. 09/551,716, filed on Apr. 18, 2000.
(63) Continuation-in-part of application No. 09/527,885, filed on Mar. 20, 2000, now abandoned.
(60) Provisional application No. 60/220,790, filed on Jul. 25, 2000.
(60) Provisional application No. 60/223,644, filed on Aug. 8, 2000.
(60) Provisional application No. 60/224,080, filed on Aug. 8, 2000.
(60) Provisional application No. 60/273,383, filed on Mar. 5, 2001.
(60) Provisional application No. 60/116,714, filed on Jan. 21, 1999.
(60) Provisional application No. 60/154,716, filed on Sep. 20, 1999.
(60) Provisional application No. 60/157,149, filed on Sep. 30, 1999.

(51) Int. Cl. G11C 7/00

(52) U.S. Cl. 365/200

(57) ABSTRACT

A programmable molecular device is provided that includes a random nano-network that includes a plurality of molecular circuit components. Preferred molecular circuit components include molecular diodes that exhibit negative differential resistance. A method of programming the molecular device may include configuring the molecular components. Configuring a molecular component may include applying a voltage across input and output leads connected to the nano-network. The voltage may be determined according to a self-adapting algorithm that programs the device to function, for example, as a logic unit or a memory unit. A molecular computer may include a plurality of programmable molecular devices that are interconnected by metallic wires.

### CROSS REFERENCE TO RELATED APPLICATIONS

This application claims the benefit of U.S. Provisional Applications Serial No. 60/220,790, filed Jul. 25, 2000, Serial No. 60/223,644, filed Aug. 8, 2000, Serial No. 60/224,080, filed Aug. 8, 2000, and Serial No. 60/273,383, filed Mar. 5, 2001. Further, the present application is a continuation-in-part of co-pending U.S. Utility applications Ser. No. ______, Attorney Docket No. 17285-28, entitled “Molecular Computer”, filed Jan. 20, 2000, and which claims the benefit of U.S. Provisional Application Serial No. 60/116,714, filed Jan. 21, 1999. Still further, the present application is a continuation-in-part of co-pending U.S. Utility application Ser. No. 08/595,130, filed Feb. 1, 1996, which claims priority of U.S. Utility application Ser. No. 08/261,867, filed Jun. 16, 1994, which in turn is a continuation-in-part of U.S. Utility application Ser. No. 07/891,605, filed Jun. 1, 1992. Yet further, the present application is a continuation-in-part of U.S. patent application Ser. No. ______ Attorney Docket Number OCR 1049, filed Apr. 18, 2000, entitled “Molecular Scale Electronic Devices” which claims the benefit U.S. Provisional Applications Serial No. 60/154,716, filed Sep. 20, 1999 and Serial No. 60/157,149, filed Sep. 30, 1999 and U.S. Utility application Ser. No. 09/527,885, filed Mar. 30, 2000. Each of the above-listed Applications is hereby incorporated herein by reference.

### STATEMENT REGARDING FEDERALLY SPONSORED RESEARCH OR DEVELOPMENT

This work was supported by funding from DARPA through the Office of Naval Research, Grant No. R13160.

### REFERENCE TO CD-ROM APPENDIX AND STATEMENT UNDER 37 C.F.R §1.52(e)(5)

One compact disk—read only memory (CD-ROM) is attached hereto in duplicate copy (“Copy 1” and “Copy 2”) in IBM-PC format, compatible with MS-Windows and MS-DOS, and incorporated-by-reference herein, in accordance with 37 C.F.R §1.52(e)(5). Copy 1 and Copy 2 are identical and contain 269 files in 1 main directory and 2 subdirectories, as identified by the following output from the MS-DOS command “dir e: /s”, where the output includes a line in standard format [month/date/year time bytes filename.extension] for each file, identifying, to one of ordinary skill in the computational arts, the date of creation, size, name, and type of each file:

[image]

[image]

[image]

[image]

[image]

[image]

[image]

### FIELD OF THE INVENTION

The present invention relates generally to programmable electronic devices, more particularly programmable nano-scale devices based on molecular circuit components.

### BACKGROUND OF THE INVENTION

Basic functions of a computer include information processing and storage. In von Neumann (serial) architectures, those arithmetic, logic, and memory operations are performed by devices that are capable of reversibly switching between two states often referred to as “0” and “1.” Semiconducting devices that perform these various functions must be capable of switching between two states at a very high speed using minimum amounts of electrical energy in order to allow the computer to perform basic operations. Transistors perform the basic switching functions in computers.

While the design and production of energy-efficient, state-of-the-art electronic devices depend increasingly on the ability to produce ever higher densities of circuit elements within integrated circuits, semiconductor-based computer technology and architecture have advanced to nearly the quantum mechanical limitations of such configurations. Soon, size and price will limit the advancement of future growth of high-performance computers. A major component that modulates these attributes of high-performance computers is the memory, particular the memory circuit density. Because of the huge data storage requirements of these instruments, a new, compact, low-cost, very high capacity, high-speed memory circuit configuration is needed. A more detailed discussion of the issues relating to downsizing of electronic devices can be found in U.S. Pat. Nos. 6,259,277, 6,219,833, 5,589,692, and 5,475,341, each of which is incorporated herein by reference.

Molecular scale electronics is a field of study that proposes the use of single molecules or groups of molecules to function as the key components in future computational devices. In particular, molecules that have strategically placed charge barriers could serve as switches. In addition to substantial size reductions, the response times of molecular devices can be in the range of femto-seconds, while the fastest present devices operate in the nanosecond regime. Thus a 10⁵ to 10⁶ increase in speed may be attainable, particularly if other circuit elements do not limit operational performance.

Optimizing the size of conventional basic units (usually the transistors) and their speed (limited by their natural temporal responses) are conflicting design goals. Therefore several trade-offs have to be made. The most important compromise in computational technology is the hardware-software duality, which materializes in the requirements of a programmed logic (memory- or software-dominant) versus wired logic (CPU-, or hardware-dominant). Components of programmed logic are smaller and able to handle larger problems than a wired logic system; however, a wired-logic is faster than a programmed-logic. At one extreme there can be a bit adder (a minimum logic unit able to sum) with a small number of logical gates that will require a large memory to obtain the results, while at the other extreme, there could be a large CPU with all specific functions wired into the system that will be able to process the entire problem, having only a small memory for the input and output data. Present technology is heavily inclined toward programmed logic, for example, a computer with a large memory and a fast but simple CPU.

An ongoing challenge in implementing molecular scale electronics has been the search for approaches for arranging molecular components into structures that have logic functions. Thus, there have been investigations into architectures that allow molecular components to be used as the basic switching elements in building logic devices. Any logic gate may be constructed from a complete set of one or more fundamental gates. More than one of these fundamental gates may be arranged in series or in parallel, or a combination of the two, to form other logic functions. Thus, there has been particular emphasis on demonstrating the functionality of fundamental gates. A NAND gate is one fundamental gates that by itself forms a complete set. A NOR gate is another fundamental gate that by itself forms a complete set. Other complete sets include the combination of an AND gate and an XOR gate, the combination of an OR gate and an XOR gate, the combinatation of an AND gate and a NOT (also termed Inverter) gate, and the combination of an OR gate and a NOT gate.

In one approach, elementary logic functions have been proposed using single molecules built up of smaller molecules bonded together. Each smaller molecule would be designed to mimic the function of a conventional circuit element. Such speculative molecules are shown in FIGS. 12, 13, and 14 of Proceedings of the IEEE, March 2000, pages 386-426, by James C. Ellenbogen and J. Christopher Love. This article is hereby incorporated by reference. The molecules shown in FIGS. 12, 13, and 14 of that reference are suggested as functioning as an AND gate, an OR gate, and a half adder, respectively. A disadvantage of this approach is the difficulty of synthesis of such proposed molecules. Further, dynamic conformational changes of the molecular segments would have the tendency to produce shorts between molecular segments.

In another approach, elementary logic functions have been demonstrated in mixed arrays of conventional circuit components and switches that contain a monolayer of millions of molecular diodes between leads. Switching function has been demonstrated in devices of monolayers of molecular diodes oriented between two conventional metal plates, such as capacitor plates. A monolayer is a layer of molecules having the thickness of one molecule. In the monolayer, molecules having opposite ends with functional groups that allow bonding to metal and have come to be termed molecular alligator clips are oriented side by side. The functionalized ends are bonded to the metallic plates. Exemplary circuits incorporating molecular monolayer-based switching devices that are disclosed to have NAND and NOR functionality are shown in FIG. 5 of the article entitled “Moletronics: A circuit design perspective”, by David P. Nackashi and Paul D. Franzon, Proc, SPIE 2001, vol. 4236 pp. 80-88. This article is hereby incorporated by reference in its entirety. Further, circuits incorporating oriented molecular monolayers are also described in U.S. patent application Attorney Docket Number OCR 1049, filed Apr. 18, 2000, entitled “Molecular Scale Electronic Devices”, which is incorporated herein by reference.

In each of the above approaches, the molecular scale devices are implementations of wired logic. This runs counter to the trend in present technology toward programmed logic. Further, wired logic tends to be less tolerant of defects than programmed logic. For industrial scale fabrication of molecular scale devices to be cost-effective and efficient the devices must be tolerant to the defects that may occur in the course of chemically assembling the devices.

Molecular scale electronics offers the possibility of computing power that dwarfs our current capabilities. Hence, a technique for creating programmed logic from molecular components in an effective, robust, and reproducible manner is desired.

### SUMMARY OF THE INVENTION

In a preferred embodiment, the present invention features a programmed logic using molecular components. Alternatively, the present invention provides a programmed memory using molecular components. The molecular components are arranged in a nanocell that forms a small programmable unit. A nanocell preferably contains as many as trillions of molecules, a few thousand of which are in a suitable orientation for switching. This provides a balance in scale between the desire for miniaturization realized by single molecule logic and the desire for robust, programmable functionality. The nanocells of the present invention have the advantage that a single nanocell that is assembled by straightforward wet chemical techniques may be programmed first to perform as one logic unit and then optionally reprogrammed to function as another logic unit. Further, the nanocells are adapted to be incorporated into standard computers in the place of conventional logic units, while providing similar functionality on a smaller scale than presently realizable in conventional silicon-based logic.

The versatility, robustness, and ease of production of the present nanocells are realized by constructing the nanocell from molecular components that are allowed to self-assemble into a structure. Unless guided by a scaffold, the molecular components assemble into a random arrangement, such as a random network. Since the network preferably extends on a scale from about 1 nm to about 2 μm, it is termed herein a nano-network. The random arrangement has the advantage that if a particular molecular component is absent from a particular location, this has little or no effect on the function of the nanocell. That is, the nanocell is programmable regardless of the precise arrangement of the molecular components. The nanocell is programmable by an iterative method termed a self-adaptive algorithm in which the algorithm adjusts to the arrangement of the molecular components.

Thus, the present invention comprises a combination of features and advantages that enable it to overcome various problems of prior devices. The various characteristics described above, as well as other features, will be readily apparent to those skilled in the art upon reading the following detailed description of the preferred embodiments of the invention, and by referring to the accompanying drawings.

### BRIEF DESCRIPTION OF THE DRAWINGS

For a more detailed description of the preferred embodiment of the present invention, reference will now be made to the accompanying drawings, wherein:

FIG. 1 is a schematic drawing of a nanocell according to an embodiment of the present invention;

FIGS. 2A and 2B are a schematic drawings of arrangement of leads according to an embodiment of the present invention;

FIG. 3 is a schematic representation of molecular components according to an embodiment of the present invention;

FIGS. 4A and 4B shows plots of the I(V) response of the molecules depicted in FIG. 3;

FIG. 5 is a schematic drawing of a molecular computer according to an exemplary embodiment of the present invention;

FIG. 6 is a schematic representation of molecular devices containing pyridyl groups as “alligator clips”;

FIG. 7 is a schematic representation of a simulated nanocell according to an exemplary embodiment of the present invention, showing “on” high conducting molecules as black lines and “off” low conducting molecules as white lines;

FIG. 8 is schematic representation of the simulated nanocell of FIG. 7 programmed to function as an Inverter gate;

FIG. 9 is schematic representation of the simulated nanocell of FIG. 7 reprogrammed to function as a NAND gate; and

FIG. 10 is schematic representation of the simulated nanocell of FIG. 7 reprogrammed to function as an Inverse Half Adder gate.

### DETAILED DESCRIPTION OF THE PREFERRED EMBODIMENT

Nanocell

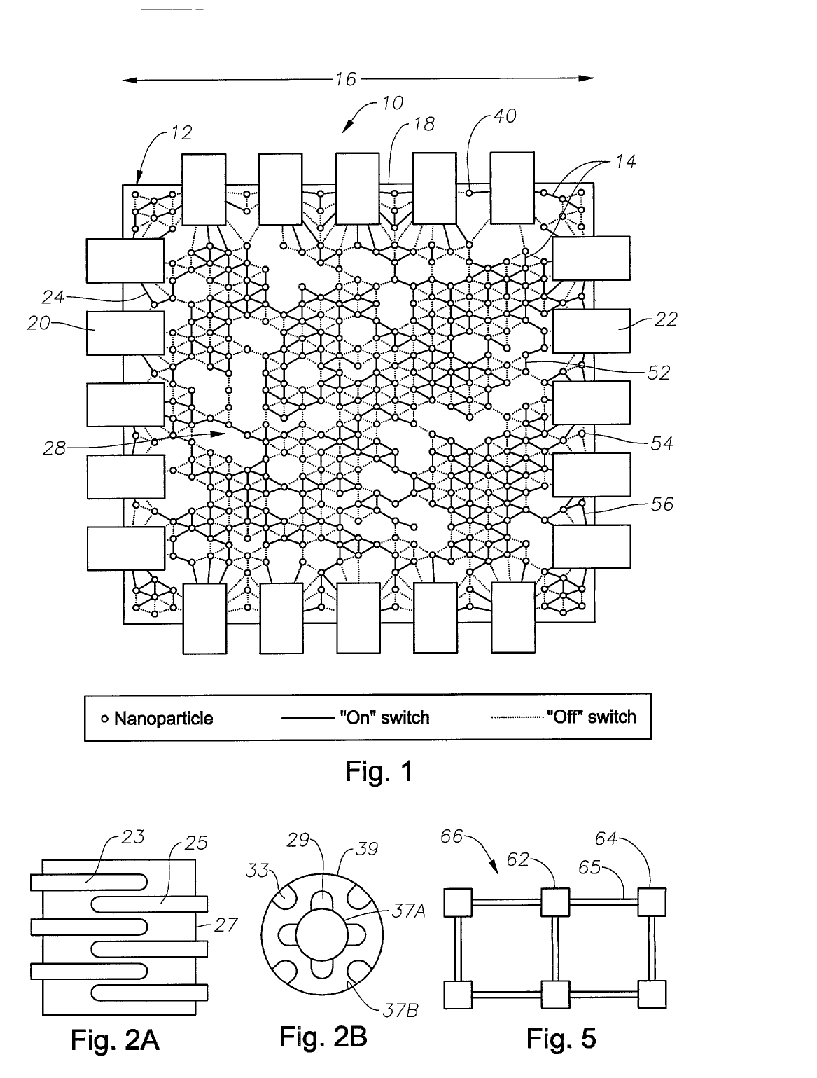

Referring initially to FIG. 1, a molecular electronic device 10 includes a nanocell 12. Nanocell 12 includes at least one and preferably a plurality of molecular circuit components 14. Nanocell 12 preferably has a linear dimension 16 of up to about 2 μm, more preferably between about 1 nm and about 2 μm. Linear dimension 16 may be the length of a side 18 of nanocell 12. Sides 18 enclose, that is define the borders containing, molecular circuit components 14. Nanocell 12 may include any number of sides and may be from one to three dimensional. Nanocell 12 is shown in FIG. 1 in a square configuration. It will be understood that alternative configurations are contemplated, such as circular, rectangular, and any other suitable configuration.

Still referring to FIG. 1, nanocell 12 preferably further includes at least one input lead 20 and at least one output lead 22. The numbers of input leads and of output leads are not crucial. The number of leads preferably is constrained only by the technique for forming leads 20, 22, such as conventional lithography, and by the size of nanocell 20. Leads 20,22 are shown at the edges of nanocell 12 in FIG. 1. It will be understood that other configurations of leads are contemplated. For example input leads 23 and output leads 25 may be interleaved, extending from edges of nanocell 27, such as shown in FIG. 2A. Alternatively, input leads 29 and output leads 33 may extend from concentric perimeters 37 defining the edges of nanocell 39, as shown in FIG. 2B.

Nano-network 20 preferably spans each input lead 20 and each output lead 22. Leads 20, 22 may be metallic and are designed to connect to conventional lithographic interconnect, such as metallic wire. Edge molecular circuit components 24 are connect to leads 20, 22, through molecular alligator clips 26. Molecular alligator clips include sticky end groups that bind to metal, based on moieties such as sulfur, oxygen, selenium, phosphorous, isonitrile, pyridine, and carboxylate. A particularly preferred sulfur-based molecular alligator clip is a thiol group. It will be understood that molecular circuit components 14 may include two, three, four, five, six or more termini, such as disclosed in Tour, J. M.; Kozaki, M.; and Seminario, J. M. “Molecular Scale Electronics: A Synthetic/Computational Approach to Digital Computing,” J. Am. Chem. Soc. 120, 8486-8493 (1998), which is incorporated by reference herein, and in U.S. Pat. No. 6,259,277, hereby incorporated herein by reference. Each terminus is preferably an end that includes a molecular alligator clip.

Still referring to FIG. 1, nanocell 12 is preferably a nano-network 28 that has a network structure in which the molecular circuit components form at least a portion or portions of the network. Nano-network 28 is a preferably a random nano-network. In particular, nano-network 28 preferably has at least one of the following elements of randomness. The x-ray crystal structure of nano-network 28 may include no appreciable peaks indicative of a periodic or a semi-periodic arrangement of molecular circuit components, preferable for length scales between about 1 nm and 2 μm. Alternatively, the x-ray crystal structure of nano-network 28 may include at least one peak indicative of a lack of characteristic length scale between about 1 nm and 2 μm. Still alternatively, nano-network 28 may have a structure that exhibits scaling behavior, multi-scaling behavior, fractal characteristics, and the like. Yet alternatively, nano-network 28 may have a structure that includes orientations of molecular circuit components 14 with respect to an arbitrary axis that follow a known random distribution, such as a Poisson distribution of several molecules between nanoparticle in the network. Still yet alternatively, nano-network 28 may have a structure that includes positions of the centers of mass of molecular circuit components 14 that follow a known random distribution, such as is characteristic of non-crystalline or amorphous solids. It will be understood that the term “random” as used herein may include any other conventional definition and may be used interchangeably with the terms “disordered” and “irregular.” Further, it will be understood that randomness may occur for certain predetermined length scales. In particular, the term random network here includes a network with little long-range order. Long-range may denote distances long with respect to the length scale of the components making up a network. A random arrangement of molecular circuit components 14 in molecular electronic device 10 has the advantage that device 10 may be fault tolerant.

Still referring to FIG. 1, in one preferred embodiment, nano-network 28 is self-assembled. As is known in the art, a self-assembled network is one that has created itself from its component parts in response to a stimulus, such as a change in reaction conditions. A self-assembled nano-network preferably has a non-predetermined structure. Further, a self-assembled nano-network in this embodiment preferably has only short range order between adjacent nanoparticles and preferably is disordered for longer length scales.

Nano-networks suitable for use in the present invention include but are not limited to nano-networks made as in the following description. Metal nanoparticles are deposited on an oxide grid. The oxide grid may be a semiconductor substrate from which material has been removed to define a hole that provides the boundaries of the nano-network. A molecular self-assembled monolayer coating each nanoparticle may be used to control the spacing between nanoparticles. Molecular switches are inserted into the inert self-assembled monolayer barrier around each nanoparticle via processes that have previously been demonstrated, and thereby inter-link adjacent nanoparticles. The processes have been disclosed in Dunbar, T. D.; Cygan, M. T.; Bumm, L. A.; McCarty, G. S.; Burgin, T. P.; Reinerth, W. A.; Jones, II, L.; Jackiw, J. J.; Tour, J. M.; Weiss, P. S.; Allara, D. L. J. Phys. Chem. B. 2000, 104, 4880-4893, hereby incorporated herein by reference.

Still referring to FIG. 1, nano-networks 28 that are trainable and include any suitable conventional molecular circuit components are contemplated. Thus, molecular circuit components 14 may be selected from among molecular wires, molecular rectifiers, molecular diodes, molecular switches, molecular resistors, molecular transistors, and the like and combinations thereof. A molecular wire, rectifier, diode, switch, resistor, or transistor is any molecule that can function in a circuit analogously to a conventional wire, rectifier, diode, switch, resistor, or transistor, respectively. Exemplary molecular wires include oligo(phenyleneethynylene), and the like. Exemplary molecular rectifiers include hexadeculquinolinium tricyanoquinodimethanide, and the like.

Still referring to FIG. 1, molecular circuit elements 14 preferably include conjugated molecular segments. The conjugated molecular segments are preferably substituted with groups at the termini that function as molecular alligator clips. Exemplary conjugated molecules that serve as conjugated molecular segments for molecular circuit elements, and exemplary conjugated molecules functionalized with molecular alligator clips are described in: Tour, J. M. “Molecular Electronics. Synthesis and Testing of Components,” Accounts of Chemical Research, volume 33, number 11, pages 791-804 (2000); Tour, J. M.; Kozaki, M.; and Serninario, J. M. “Molecular Scale Electronics: A Synthetic/Computational Approach to Digital Computing,” J. Am. Chem. Soc. 120, 8486-8493 (1998); Dirk, S. M., et al. “Accoutrements of a molecular computer: switches, memory components and alligator clips,” Tetrahedron 57, pp. 5109-5121 (2001), each hereby incorporated herein by reference. Further, molecular circuit components 14 may include any of the molecules, conductive organic material, or conductive paths disclosed in U.S. patent application Ser. No. ______ Attorney Docket Number OCR 1049, filed Apr. 18, 2000, entitled “Molecular Scale Electronic Devices”, which is incorporated by reference herein.

Molecular circuit element 14 is preferably a molecule that exhibits negative differential resistance. Conventional resonant tunneling diodes also exhibit negative differential resistance. However, conventional resonant tunneling diodes are based on gallium arsenide. Negative differential resistance is a particular useful property in designing logic as it allows negation.

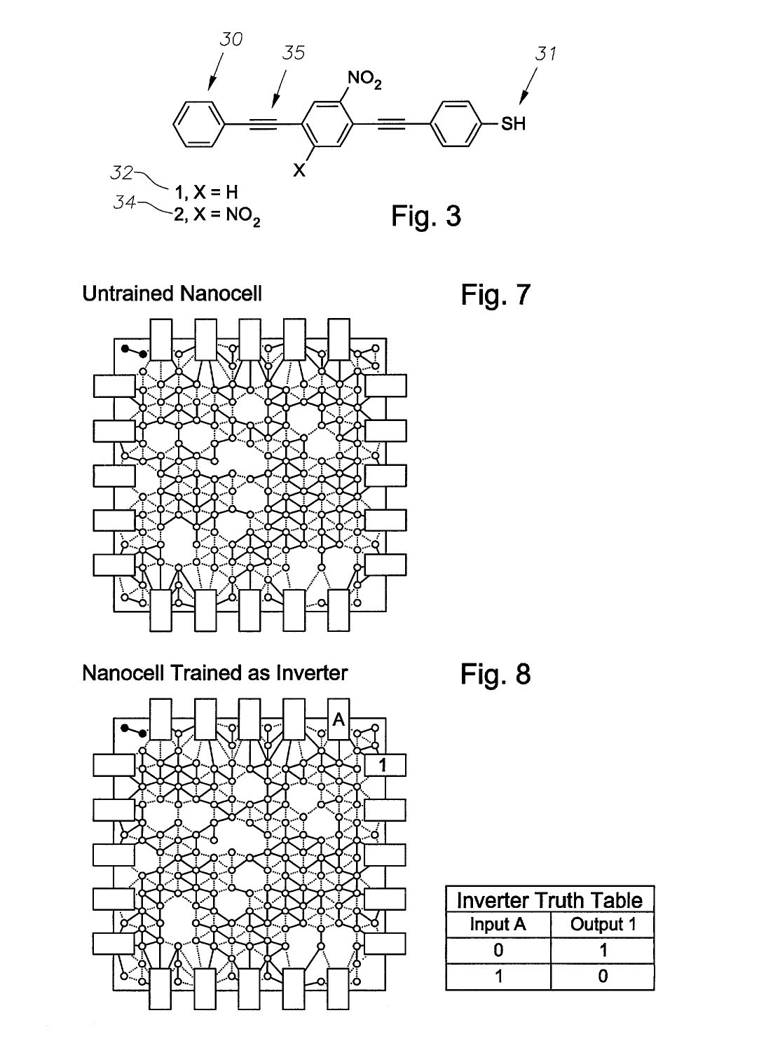

Referring now to FIG. 3, a molecular circuit component 14 may be a molecular diode 30. Exemplary molecular diodes include a mono-nitro substituted oligophenylene 32, in particular 4,4′-diphenyleneethynelene-2′-nitro-1-benzenethio and a di-nitro substituted oligophenylene 34, in particular 2′,5′-dinintro-4,4′-diphenyleneethynylene-1-benzenethiol.

Alternative molecular diodes include the dithiol substituted analogs of molecules 32 and 34, in particular 4,4′-diphenyleneethynelene-2′-nitro-1,4″-benzenedithiol and 2′,5′-dinitro-4,4′-diphenyleneethynylene-1,4″-benzenedithiol, respectively. Each of these molecules includes a thiol group at each end. Such a configuration is preferred for molecular circuit elements 14 that contact gold at each end. As used herein the term molecular switch also encompasses these molecules when they are in an electrical environment that allows them to function as a switch. The electrical environment may be created by adding or changing substituents, by bonding another molecule to the molecular diode, or by connecting the molecular diode, such as by a molecular alligator clip, to a circuit element.

Nanocell 12 may further include nanoscale components 40. Nanoscale components 40 preferably are arrayed as part of nano-network 28. Nanoscale components may have functionality of electrical connectors, aiding the formation of molecular components 14 into a conductive network. Further, nanoscale components may have functionality of electronic circuit components, such as conductance, capacitance, resistance, impedance, and the like. Exemplary nanoscale components include nanotubes, nanoparticles, nanorods, and combinations thereof. Nanoparticles may be metallic, semiconducting, dielectric, and the like. Exemplary nanoparticles and nanotubes are described in Reed, M. A. and Tour, J. M. Scientific American 282, pp. 86-93 (2000), hereby incorporated herein by reference. Exemplary nanorods are described in Martin, B. R., et al. “Orthogonal self-assemble on colliodal gold-platinum nanorods,” Adv. Mater. 11, pp. 1021-1025 (1999), hereby incorporated herein by reference.

It will be understood that where one molecular circuit component 14 is depicted by a line in FIG. 1, a plurality of molecular circuit components 14 may be substituted. For example, a plurality of molecular circuit components 14 may contact each of a pair of nanoscale components 40, spanning the nanoscale components.

Referring still to FIG. 1, in an exemplary arrangement, a nanocell 10 includes molecular switches 52 and nanopaiticles 54. Nanoparticles 54 are preferably metallic, more preferably gold. Molecular switches 52 are preferably switches with thiol molecular alligator clips at each end, more preferably 2′,5′-dinitro-4,4′-diphenyleneethynylene-1,4″-benzenedithiol. Edge molecular switches 56 connect to input leads 20 and output leads 22. Molecular switches 52 interconnect nanoparticles 54. Interconnect is here used in the sense of enabling electrical continuity. In this sense, in an alternative view, nanoparticles 54 interconnect molecular switches 52. Further, the electrical continuity supplied by a molecular switch 52 need not be permanent and can be interrupted by configuring molecular switch 54.

Nano-network 28 is preferably formed by molecular switches 52 and nanoparticles 54. In particular, nanoparticles 54 are preferably arrayed with little or no order. Further, molecular switches 52 interconnect nanoparticles 54. Not all nanoparticles 54 connect to other nanoparticles 54 and some nanoparticles 54 are connected to more than one or more than two other nanoparticles, and connections may be randomly distributed.

It will be understood that the impedance properties of a nanocell 12 may be optimized by varying any one or combination of a metal of nanoparticles 54, a conjugated backbone of molecular circuit component 14, the moiety for the alligator clip of molecular circuit component 14, the geometry of leads 20, 22, and other suitable properties for adjusting impedance.

It will further be understood that molecular circuit components 14 may be multiple state molecules, such as three, four, five, or six state molecules. For example, C₆₀ has six independent states that are attained by incrementally taking up six electrons. Thus, molecular circuit components 14 are not limited to binary “0” and “1”, or “on” and “off” logic and, for example, tertiary and quaternary logic are contemplated.

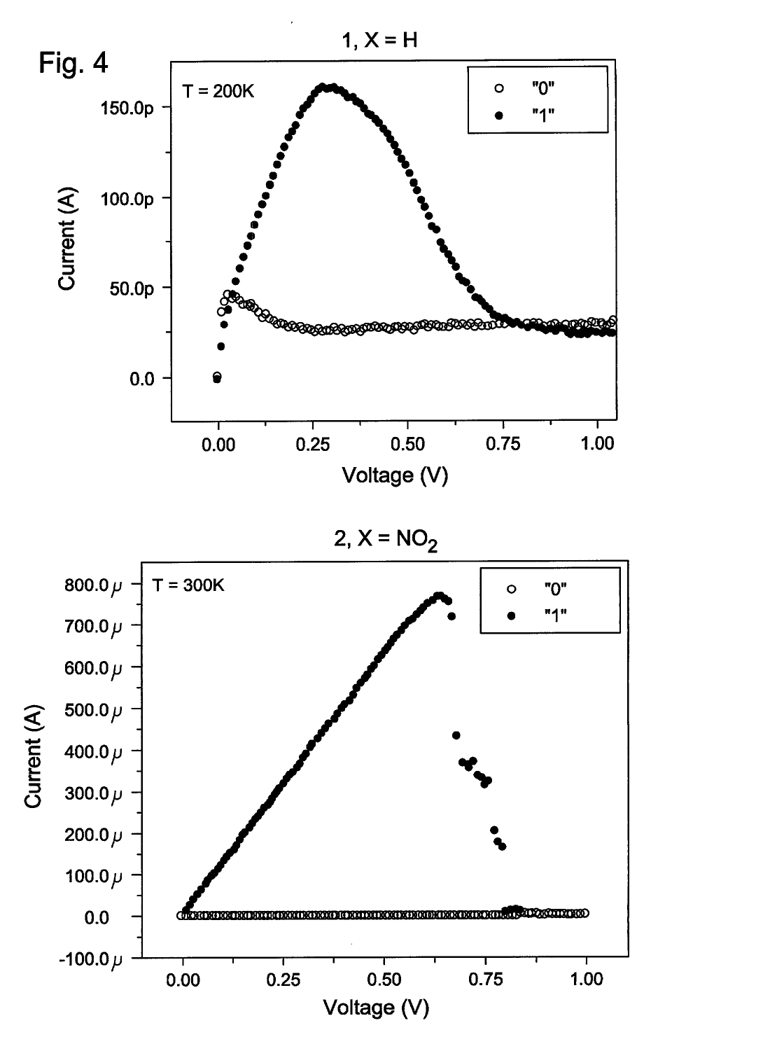

Referring now to FIG. 5, a plurality of programmable electronic devices 62, preferably nanocells 64, may be interconnected by standard lithographically produced metallic wires to form a molecular computer 66. Nanocells 64 are preferably constructed as described above with respect to FIG. 1, more preferably as shown, for example, in FIG. 4. Any conventional architecture for interconnection by wires 65 is contemplated.

Programmability

Referring again to FIG. 1, molecular electronic device 10 is preferably programmable. More particularly, molecular electronic device 10 is preferably programmable with a self-adaptive algorithm. As used herein, a self-adaptive algorithm is one that can “evolve” using an iterative process in which the algorithm queries and adjusts a system in order to move the system toward a desired state. More particularly, self-adaptive algorithms are a class of algorithms that include a set of rules for comparing an actual outcome of a system to a target outcome, and adjusting an input to the system based on a function of the difference between the actual outcome and the target outcome. A next actual outcome is associated with the adjusted input according to the behavior of the system. By repeatedly adjusting the inputs, the actual outcome converges to the target outcome. In this way, the self-adaptive algorithm trains the system.

Molecular device 10 is preferably programmable by a self-adaptive algorithm for configuring molecular circuit components 14.

In one preferred embodiment, molecular circuit components 14 are preferably configurable by applying a voltage across leads 20, 22. For example, molecular circuit components 14 may include molecules for which a conductivity-affecting property is adjustable by applying a voltage across leads 20, 22. The conductivity-affecting property that is adjusted is preferably selected from the group consisting of: charge, conformational state, electronic state, and the like, and combinations thereof.

It will be understood that molecular circuit components 14 may be configurable by other methods

Oligophenylene-based molecular wires and switches are exemplary of molecules whose conductivity is affected by charge, electronic state, and conformational state. It is believed that applying a voltage across these molecules can effect transitions between electronic states. The voltages may cause the molecule to hold an electron; thus increasing its charge. Further, when charged, the molecule transitions to an excited electronic state. The phenyl rings rotate with respect to each other so that electronic orbitals, such as pi-orbitals, align, forming a molecular orbital extending the length of the molecule. In the presence of an applied voltage, it is believed that electronic continuity is established through the molecular orbitals and the molecule conducts. A description of a molecular mechanism of switching functionality is contained Donhauser, Z. J. et al., Science 292, pp. 2303-2307 (2001), hereby incorporated herein by reference.

In a preferred arrangement, the electrical characteristics of the materials used to make the leads contacting the molecule are matched to the energetics of the molecular electronic transitions. In particular, it is preferred that the Fermi energy of the metal contacting a conjugated molecular circuit element are close in energy to the lowest unoccupied molecular orbital (LUMO) energy of the molecular circuit element. This has the advantage of optimizing the impedance characteristics of the connection between the metal and the molecule.

Operation of molecular switches differs from molecular wires. The conductivity of switches can be switched to a state that is stable for a relatively long time by applying and then removing a voltage. Referring to FIG. 3, stability times of at least 24 hours have been obtained with molecule 34. Further, it is expected that improved sealing of the system containing a molecular switch; use of similar oligophenylene-based molecules with multiple nitro groups; or use of new classes of molecules will permit longer stability times, such as days or months. A preferred molecular switch is configurable by applying a switching voltage and operates in either a high or low conductivity state by applying an operating voltage that is less than the switching voltage.

Referring now to FIG. 3, operation of a molecular switch is exemplified by operation of a molecule 34. When a switching voltage above 2.0V is applied to molecules 34, molecules 34 switch to the high conductivity state and when a corresponding voltage below −2.0V is applied the molecules 34 will switch to a low conductivity state. The switching voltage is preferably between about 0.2 and 3.0V for the high state and −0.2 and −3.0V for the low conductivity state. The high conductivity state is associated with the I(V) curve that is traced by black dots and the low conductivity state is associated with the lower I(V) curve, traced by white dots, in FIG. 4. The degree of differentiation between the high and low conductivity states is determined by the indifference between these two curves. When an operating voltage between about −2 V and 2V is applied to molecules 36 they conduct according to the state, high or low conductivity, that they were most recently switched to. A molecule in the high conductivity state will also exhibit low conductivity if a voltage exceeding the negative differential resistance (NDR) limit is applied. The degree of differentiation between high and low conductivity of a molecule in the high conductivity state that is due to the NDR effect is determined by the ratio between the peak and valley on the I(V) curve traced by the black dots. The absolute value of the operating voltage is preferably between about 0.2 and about 2.0V.

Referring again to FIG. 1, nanocell 12 is preferably programmable by an algorithm for setting molecular switches 54. Molecular switches 54 are preferably settable by applying a voltage across leads 20, 22. It is preferred that a self-adaptive algorithm for programming nanocell 10 be capable of learning voltage combinations that can be applied to leads 20, 22 that will configure remote molecular switches, that is molecular switches not directly connected to leads 20, 22.

It will be understood that the type of the self-adaptive algorithm is not critical. Any suitable conventional self-adaptive algorithm capable of training a network such as nano-network 28 may be used. Exemplary self-adaptive algorithms include genetic algorithms, simulated annealing algorithms, reinforcment learning algorithms, temperoral difference algorithms, go with the winner algorithms, and the like. The principles of self-adaptive algorithms are described in Goldberg, D. E., Genetic algorithms in Search, Optimization, and Machine Learning, (Addison Wesley, Reading, Mass., 1989), pp. 1-15 and 221-229, hereby incorporated herein by reference.

Self-adaptive algorithms have the advantage of being error-resilient. Further, the use of a self-adaptive algorithm also provides the advantage of fault tolerance. Thus, molecular electronic device 10 is adapted to be manufactured by methods of self-assembly that can be implemented on an industrial scale with cost-effective reliability. The self-adaptive algorithm may be encoded in an auxiliary computer.

An advantage of the present invention is that the programmability of molecular electronic device 10 means that the device, as first assembled, need not function as a specified logic device. Thus, molecular electronic device 10, nanocell 12, and nano-network 28 need not have a predetermined structure. Nanocell 12, and in particular nano-network 28 may be self-assembled into an indeterminate structure that may be random. A self-adaptive algorithm may be used to program device 10 to function as a desired device.

In a preferred embodiment, device 10 is programmable to function as a logic unit selected from the group consisting of AND, OR, XOR, NOR, NOT, and NAND gates and the like. Thus, in this embodiment, when device 10 has been programmed, it is a programmed logic device with the logic element being selected from the group consisting of AND, OR, XOR, NOR, NOT, NAND, and the like.

In another preferred embodiment, device 10 is programmable to function as a logic unit selected from the group consisting of an Adder, a Half-Adder, a Multiplexor, a Decoder, or and the like. Thus, in this embodiment, when device 10 has been programmed, it is a programmed logic device with the logic element being selected from the group consisting of an Adder, a Half-adder, a Multiplexor, a Decoder, and the like. In yet another preferred embodiment, device 10 is programmable to function as a memory unit.

It will be understood that device 10 preferably may function as any gate having a truth table supported by input/output pins.

Device 10 is preferably reprogrammable. In particular, device 10, initially programmed to function as one of the above-described logic or memory units can be reprogrammed to function as another of the above-described logic or memory devices. Thus, device 10 has the advantage of versatility.

The above-described programmability preferably is achieved by using the preferred topologies of nanocell structures described above in combination with the preferred programming methods described below.

Programming Method

A preferred method of making an electronic component includes providing a self-assembled nanocell and programming the nanocell to function as the electronic component. The nanocell is preferably a nanocell according to any of the embodiments described above.

Programming the nanocell preferably includes configuring the molecular circuit components. Configuring the molecular circuit components preferably includes adjusting a conductivity-affecting property of at least one of the molecular circuit components by applying a voltage across the input lead and the output lead. The conductivity-affecting property may be selected from among any of the above-described conductivity-affecting properties.

Programming the nanocell preferably further includes testing the performance of the nanocell. For example, the performance may be tested by comparing input/output operating voltage relationships of the nanocell to a target truth table, such as a desired logic truth table.

Programming the nanocell preferably still further includes repeating the steps of configuring the molecular circuit components and testing the performance of the nanocell until the nanocell functions as the electronic component desired. For example, the steps may be repeated until the input/output operating voltage relationships match, within a desired predetermined error, the above-described target truth table. Once programmed, the electronic component serves as any of the above-described logic or memory units or other similar device.

Providing a self-assembled nanocell preferably includes allowing a plurality of nanoscale components to self-assemble into a random array, allowing the plurality of molecular circuit components to self-assemble into an interconnected network between the nanoscale components, and bonding the molecular circuit components to the nanoscale components with molecular alligator clips. The random array may be an array with short-range order and long-range disorder. The molecular alligator clips may include any of the above-described moieties useful as molecular alligator clips. A preferred moiety is a thiol group. The nanoscale components may be, for example, any of the above-described nanoscale components. The molecular circuit components may be, for example, any of the above-described molecular circuit components.

Any embodiment described above for programming or training a nanocell can be used to assemble a computer from a plurality of nanocells. One method of making a computer preferably includes providing a plurality of trained self-assembled nanocells, interconnecting the trained nanocells to a plurality of untrained nanocells, and allowing the trained nanocells to train the untrained nanocells. An advantage of the above method is that the trained nanocell is used in the bootstrap training of the untrained nanocell. Thus, the method may include hierarchically repeating interconnecting the nanocells and using the latest trained nanocells to train the untrained nanocells. In this way, a molecular computer may be rapidly and efficiently made from a plurality of nanocells.

### EXAMPLES

### Example 1

Synthesis of Conjugated Molecules

Switches and Memory Components

In an effort to improve the electron storage time by adding more nitro groups, synthetic targets 1 and 2 were chosen. The SAc group is easily cleaved to the free thiol (SH) upon treatment with acid or base. The synthesis of compound 1 is outlined in scheme 1.

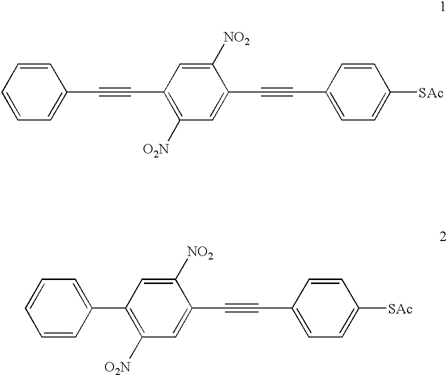

The synthesis of 1 began by Sonogashira coupling 2,5-dibromo-4-nitroaniline (3) to phenylacetylene affording 4 which was subjected to an HOF oxidation forming 5. A final coupling produced desired compound 1 in 24% yield. The low yield in this coupling may be indicative of the easily deprotected thiol or a stable palladacycle intermediate that formed during coupling.

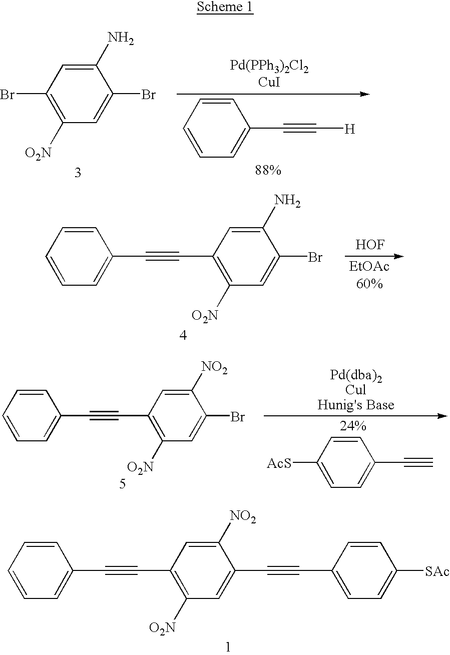

In order to conduct electrons all the phenyl rings in the conjugated molecule should be preferentially planar to each other. If a phenyl group replaces the terminal phenylethynyl group, the system cannot attain planarity. In an effort to determine the effect of a rotational barrier (i.e. conduction barrier), the synthesis of compound 2 was initiated via a Suzuki coupling of 2,5-dibromo-4-nitroacetanilide (6) to phenyl boronic acid to form compound 7. The acetyl group was removed to provide the aniline (8) functionality that would subsequently undergo an HOF oxidation to afford 9 in nearly quantitative yield. A final Sonogashira coupling provided 2.

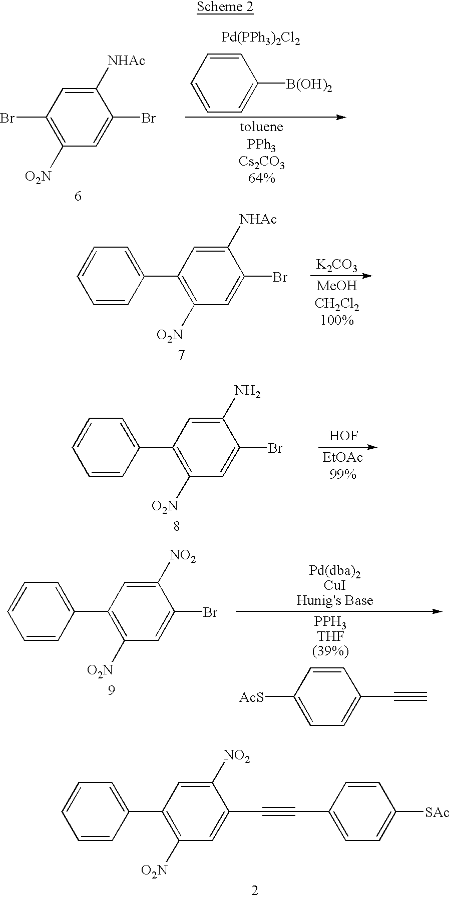

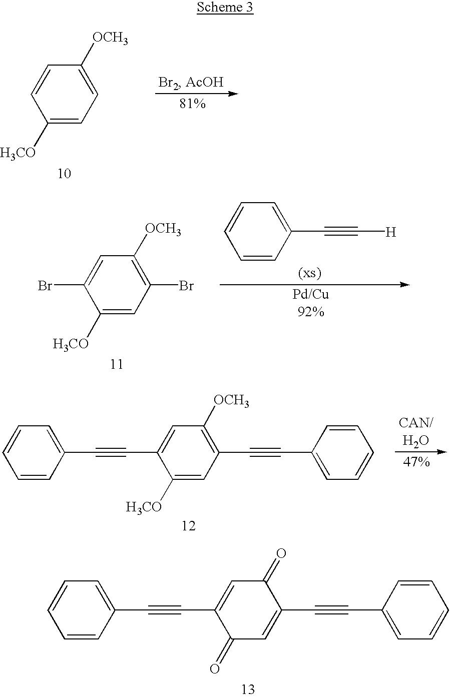

13 was synthesized for the purpose of studying the electrochemical properties of the quinone-containing molecular system. Scheme 3 shows the synthesis of 13 from 1,4-dimethoxybenzene (10). 10 was converted to 11 using bromine and glacial acetic acid in good yield. Compound 11 was then cross-coupled with an excess of phenylacetylene to afford compound 12 which was then oxidized to the quinone affording desired compound 13. This synthetic route had to be used because quinones generally cannot be used in the palladium-catalyzed couplings since quinones are known to oxidize palladium(0) to palladium(II), terminating the catalytic cycle. Ceric ammonium nitrate (CAN) is a mild and neutral oxidizing agent known to generate quinones from dimethoxybenzenes and therefore was a logical choice for this procedure.¹⁸ This oxidation afforded the desired quinone compound in 47% yield. The optimum conditions for the oxidation have not yet been obtained for these systems.

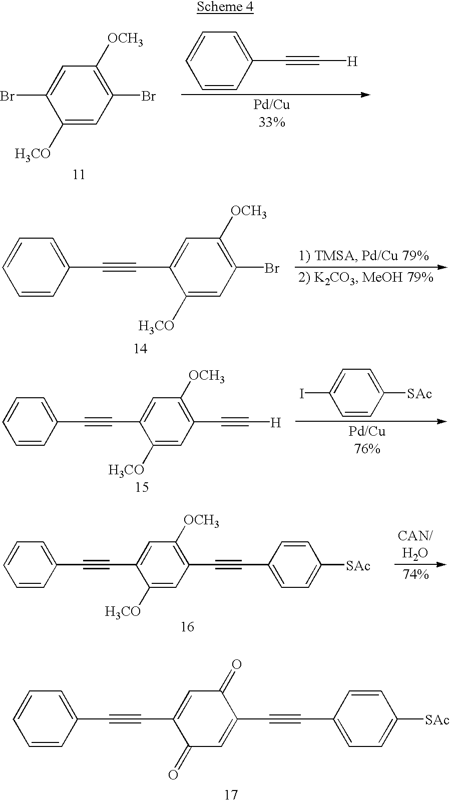

Scheme 4 shows the synthesis of the quinone-containing molecular system with one thioacetate group serving as a protected alligator clip. Cross-coupling of 11 with phenylacetylene afforded 14 in a modest yet statistically expected yield of 33% due to the equal reactivity of both aryl bromides of 11 under Sonogashira coupling conditions. 15 was prepared by the cross-coupling of trimethylsilylacetylene with 14 followed by deprotection of the alkyne to afford 15. Further palladium-catalyzed cross-coupling with 4-iodobenzenethioacetate afforded compound 16. The final compound 17 was obtained in 74% yield via the CAN oxidation. However, this yield was an isolated incident. Other attempts resulted in much lower yields (˜20%). More work is underway to optimize the conditions of this CAN oxidation.

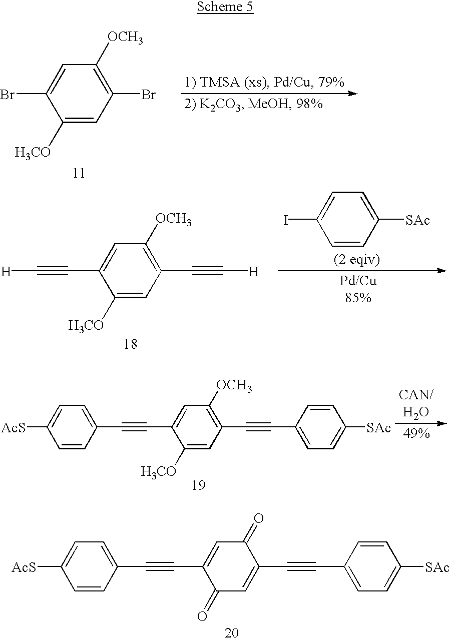

Scheme 5 shows the synthesis of the quinone-containing molecular system with alligator clips on both ends (5). This compound can be used to crosslink metallic nanoparticles for bridging connections in future molecular electronic devices. 11 was cross-coupled with an excess of trimethylsilylacetylene followed by a subsequent deprotection to cleanly afforded the diyne 18. This was subsequently cross-coupled with 2 equivalents of 4-iodobenzenethioacetate to afford compound 19. Finally, 19 was oxidized using the CAN procedure to generate 20 in modest yield.

Alligator Clips

The synthesis of several compounds containing a pyridine alligator clip for incorporation into a molecular electronic device began with compound 21. The synthesis of 22 was accomplished by coupling pyridine 21 with 2,5-dibromonitrobenzene as shown in eq 1. The low yield may be due to a stable copper acetylide formed after the TMS group is cleaved. If an in situ deprotection was not used, the pyridine alkyne proved to be unstable.

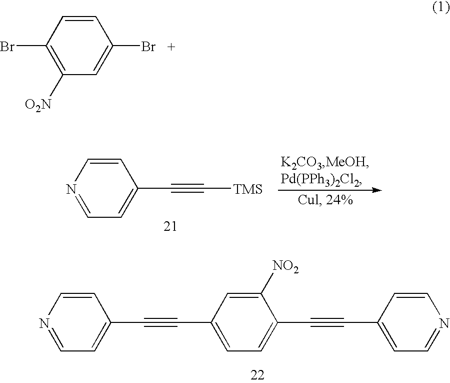

24 was synthesized according to Scheme 6. The synthesis began by coupling one equivalent of 21 to 2,5-dibromonitrobenzene selectively to the position ortho to the nitro group affording 23. Coupling 23 to phenylacetylene to produce 24 completed the synthesis.

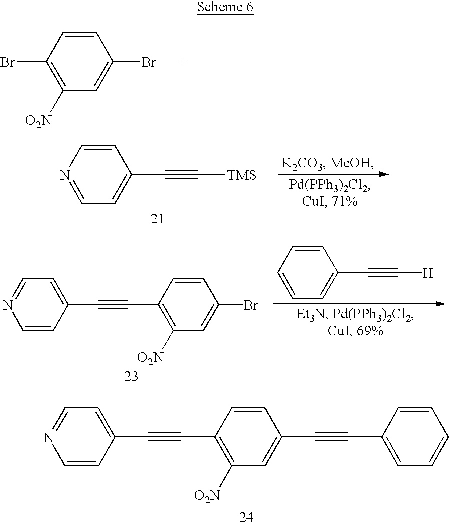

The synthesis of compound 26 was initiated to study the effect of the nitro group in relation to the chemisorbed pyridine alligator clip. To this end, compound 24 was synthesized in a manor analogous to the synthesis of 23 as shown in Scheme 7. Coupling one equivalent of phenylacetylene selectively to 2,5-dibromonitrobenzene to produce 25 then coupling to 21 to afford 26 in good yield completed the synthesis.

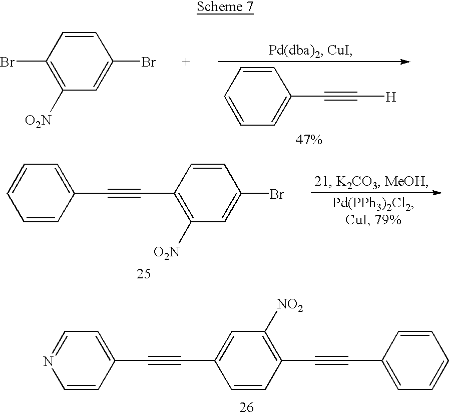

Linker 28 was synthesized according to Scheme 8. The synthesis commenced with the coupling of 2,5-dibromo-4-nitroacetanilide with excess trimethylsilylacetylene to give 27, which was then deprotected in-situ and coupled with 4-iodopyridine to produce 28 in poor yield. The low yield of the coupling reactions could be due to a cyclization process between the nitro and the alkyne unit.

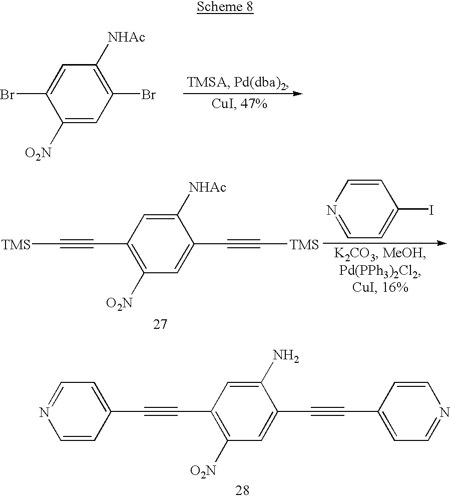

Compound 31 was synthesized in an effort to form a SAM via the protected benzenethiol terminal group enabling the pyridyl end of the molecule to serve as a better top contact with metal than a phenyl when incorporated into a device. 31 was synthesized by coupling the 2,5-dibromo-4-nitroacetanilide with 21 in a low yield to afford compound 29. 29 was then coupled with trimethylsilylacetylene, followed by deprotection with potassium carbonate to yield 30. finally, 30 was coupled with 4-iodobenzenethioacetate, which afforded the molecular device 31 in good yield (75%).

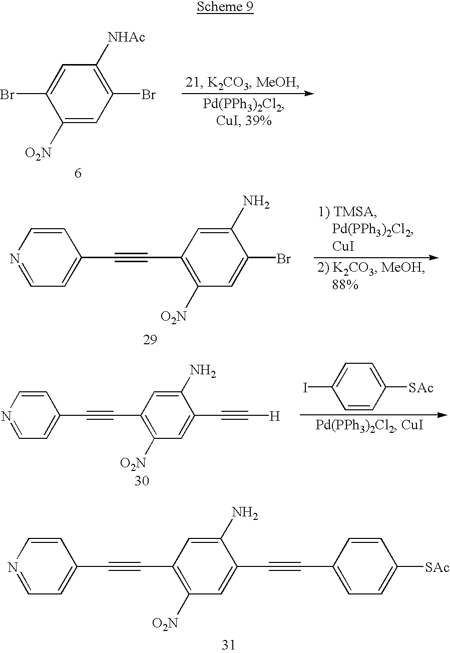

32 was synthesized to study the effect of a rotational barrier analogous to that described for 2. The synthesis of 32 began with previously synthesized 7 and coupling to 21 in good yield as shown in eq 2.

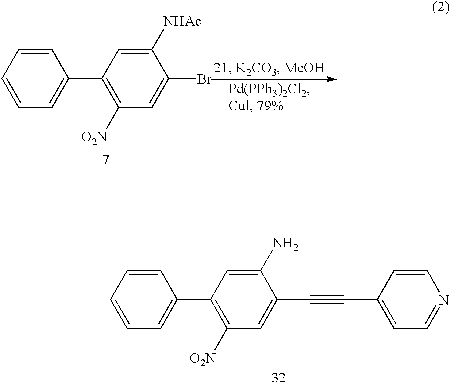

Compound 34 was synthesized according to eq 3 using the previously described 33. Compound 34 is analogous to a thiol terminated nitroaniline that previously exhibited negative differential resistance (NDR) in a device embodiment.

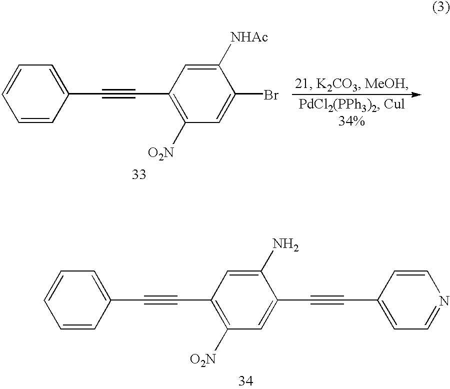

In addition to the pyridine containing systems, three potential memory and switching components terminated by diazonium salts were synthesized. 38 is analogous to the thioacetyl terminated NDR and memory component ¹ and the pyridyl terminated 24. The synthesis of 38 began by coupling 35⁷ to 2,5-dibromonitrobenzene in moderate yield to afford 36 which was then coupled to phenylacetylene to produce compound 37. Diazotization of 37 produced the completed molecule 38 in good yield.

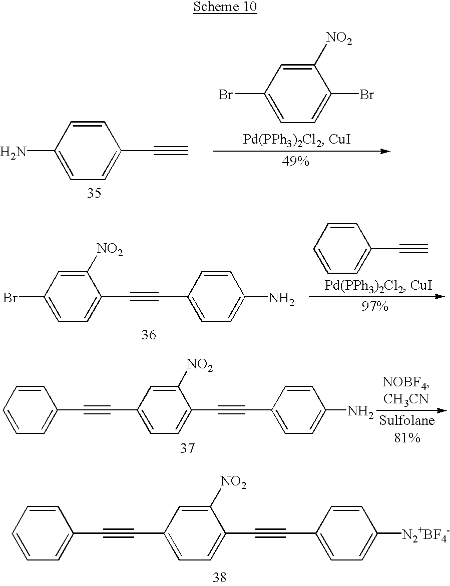

40 is similar in structure to 26 except the pyridyl group has been replaced with the aryl diazonium salt. The synthesis of 40 is shown is Scheme 11. Coupling aniline 35 to nitrocompound 25 produced diazonium precursor 39 in moderate yield. Diazotization of aniline 42 afforded desired product 37.

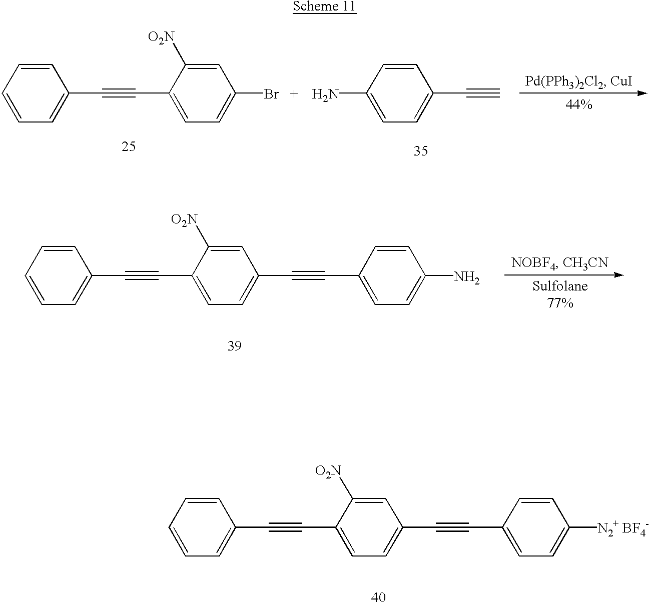

Nanoparticle linker 43 was Synthesized according to Scheme 12. Starting from dinitro 41 and coupling aniline 35 afforded dinitrodianiline 42 which was subsequently diazotized to produce 43 in good yield.

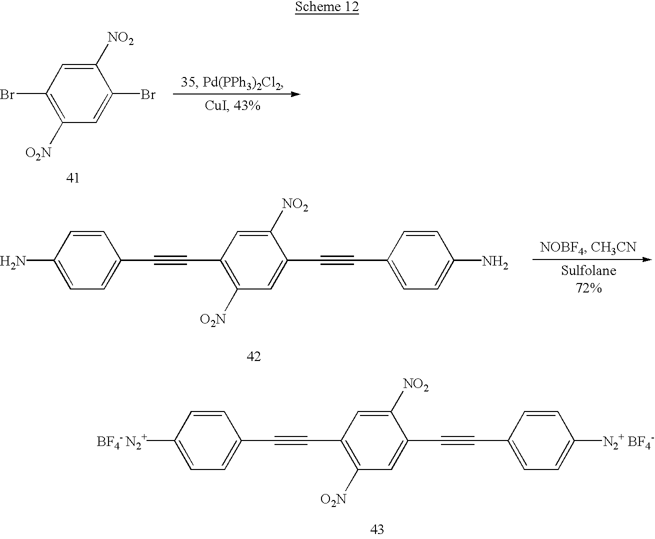

Experimental

General Procedure. All reactions were carried out under a dry nitrogen atmosphere unless noted. Reagent grade diethyl ether, and tetrahydrofuran (THF) were distilled under nitrogen from sodium benzophenone ketyl. Reagent grade dichloromethane (CH₂Cl₂) was distilled from calcium hydride (CaH₂) under nitrogen. Triethylamine and N,N-diisopropylamine (Hünig's base) were distilled over CaH₂ under a nitrogen atmosphere. Bulk hexanes were distilled prior to use. Gravity column chromatography and flash chromatography were carried out using 230-400 mesh silica gel from EM Science. Thin layer chromatography (TLC) was performed using Merck 40 F₂₅₄ on a thickness of 0.25 mm.

General Pd/Cu Coupling Reaction Procedures. To an oven dried glass screw capped tube were added all solids including the aryl halide (bromide or iodide), alkyne, copper iodide, triphenylphosphine and palladium catalyst. The atmosphere was removed via vacuum and replaced with dry nitrogen (3×). THF, remaining liquids, and Hünig's base or triethylamine were added and the reaction was heated in an oil bath while stirring. Upon cooling the reaction mixture was filtered via gravity filtration to remove solids and diluted with CH₂Cl₂. The reaction mixture was extracted with an aqueous solution of ammonium chloride (NH₄Cl) (3×). The organic layer was dried with magnesium sulfate and filtered The solvent was then removed in vacuo.

General Procedure for the Deprotection of Trimethylsilyl-Protected Alkynes. To a round bottom flask equipped with a stir bar were added the protected alkyne, potassium carbonate (5 equiv per protected alkyne), methanol, and methylene chloride. The reaction was heated, and upon completion the reaction mixture was diluted with methylene chloride and washed with brine (3×). The organic layer was dried over MgSO₄, and the solvent removed in vacuo.

General HOF Oxidation Procedure. To a 125 mL polyethylene bottle were added H₂O (2 mL) and CH₃CN (60 mL) and cooled to −20° C. F₂ (20% in He) was then bubbled through the solution at a rate of 50 sccm for 2 h. The resulting HOF/CH₃CN solution was purged with He for 15 min. The species to be oxidized was added in acetone or ethyl acetate (10 mL) and mixed at −20° C. for 5 min before being neutralized by pouring into a saturated NaHCO₃ solution. The organic phase was then separated, dried over MgSO₄ and the solvent were removed in vacuo.

General Procedure for the Diazotization of Anilines with Nitrosonium Tetrafluoroborate in the Acetonitrile—Sulfolane System. NOBF₄ was weighed out in a nitrogen filled dry box and placed in a round bottom flask equipped with a magnetic stirring bar and sealed with a septum. Acetonitrile and sulfolane were injected in a 5 to 1 volume ratio and the resulting suspension was cooled in a dry ice/acetone bath to −40° C. The solution of the aniline was prepared by adding warm sulfolane (45-50° C.) to the amine under a nitrogen blanket, sonication for 1 min and subsequent addition of acetonitrile (10-20% by volume). The aniline solution was then added to the nitrosonium salt suspension over a period of 10 min. The reaction mixture was kept at −40° C. for 30 min and was then allowed to warm to the room temperature. At this point, the diazonium salt was precipitated by the addition of ether or dichloromethane, collected by filtration, washed with ether or dichloromethane and dried. Additional purification of the salt was accomplished by re-precipitation from DMSO by dichloromethane and/or ether.

4-Ethynlphenyl-2,4-dinitrobromobenzene (5). 2-Bromo-4-nitro-5-ethynlphenylaniline (490 mg, 1.48 mmol) in ethyl acetate (10 mL) was oxidized according to the general HOF oxidation procedure to yield 320 mg (60%) of a yellow solid. IR (KBr) 3442.7, 3101.4, 2216.8, 1610.6, 1540.9, 1461.3, 1384.8, 1358.7, 1337.1, 1264.4, 906.2, 849.6, 824.4, 760.2, 689.8 cm⁻¹. ¹H NMR (400 MHz, CDCl₃) δ8.41 (s, 1 H), 8.09 (s, 1 H), 7.60-7.58 (m, 2 H), 7.41-7.39 (m, 3 H). ¹³C NMR (100 MHz, CDCl₃) δ152.1, 150.4, 132.7, 131.7, 131.0, 130.7, 129.1, 121.5, 119.8, 113.9, 102.0. HRMS Calc'd for 345.9589. Found: 345.9585.

2′,5′-Dinitro-4,4′-diethynylphenyl-1-thioacetylbenzene (1). 4 (300 mg, 0.86 mmol), 4-ethynyl(thioacetyl)benzene (183 mg, 1.04 mmol), bis(dibenzylideneacetone)palladium (12 mg, 0.02 mmol), copper(I) iodide (4 mg, 0.02 mmol), triphenylphosphine (13 mg, 0.05 mmol), Hunig's base (0.60 mL) and THF (20 mL) were reacted according to the general coupling procedure. The reaction mixture was heated at 60° C. overnight and worked up according to the procedure above. The crude compound was purified via flash chromatography (silica, 3:1 dichloromethane:hexane) to yield 90 mg (24%) of a bright yellow solid. IR (KBr) 2220.2, 1705.2, 1545.5, 1499.81, 1396.8, 1337.5, 1286.1, 1252.1, 1108.6, 1087.2, 953.2, 926.0, 868.3, 827.2, 756.7, 684.1, 618.3 cm⁻¹. ¹H NMR (400 MHz, CDCl₃) δ8.34 (d, J=0.4, 1 H), 8.35 (d, J=0.4, 1 H), 7.63-7.59 (m, 4 H), 7.46-7.40 (m, 5 H), 2.49 (s, 3 H). ¹³C NMR (100 MHz, CDCl₃) δ193.2, 151.1, 134.7, 133.1, 132.7, 131.0, 130.7, 129.1, 122.8, 121.7, 119.4, 118.6, 102.4, 100.9, 84.8, 83.5, 30.8. HRMS Calc'd for 442.0623. Found: 442.0634.

2-Bromo-4-nitro-5-phenylacetanilide (7). 6 (676 mg, 2 mmol), triphenylphosphine (52 mg, 0.2 mmol), phenylboronic acid (293 mg, 2.4 mmol), bis(triphenylphosphine)palladium dichloride (70 mg, 0.1 mmol), and cesium carbonate (977 mg, 3 mmol) were placed in a 100 mL round bottom flask and the atmosphere was removed and replaced with nitrogen. Toluene (30 mL) was added and the reaction was heated at 60° C. for 2 d. The reaction was worked up by diluting with ether, washing with aqueous ammonium chloride (2×), drying over MgSO₄, and removing the solvents in vacuo. The crude product was purified via flash chromatography (CH₂Cl₂) to yield 430 mg (64%) of a white solid. IR (KBr) 3373.6, 3322.4, 3086.5, 1774.0, 1681.7, 1568.9, 1528.8, 1445.8, 1389.4, 1358.6, 1245.8, 1179.1, 1112.5, 1056.1, 1030.4, 999.6, 872.0, 850.9, 768.9, 697.1 cm⁻¹. ¹H NMR (400 MHz, CDCl₃) δ8.54 (s, 1H), 8.15 (s, 1H), 7.80 (br s, 1H), 7.40-7.38 (m, 3H), 7.29-7.27 (m, 2H) 2.26 (s, 3H). ¹³C NMR (100 MHz, CDCl₃) δ168.44, 143.77, 139.34, 137.74, 136.81, 128.67, 128.51, 128.47, 127.85, 123.31, 110.59, 25.05. HRMS Calc'd for C₁₄H₁₁BrN₂O₃: 333.9953. Found: 333.9952.

2-Bromo-4-nitro-5-phenylaniline (8). 7 (500 mg, 1.49 mmol), potassium carbonate (1.031 g, 7.46 mmol), methanol (30 mL), and mnethylene chloride (30 mL) were added to a 100 mL round bottom flask and stirred at room temperature under a nitrogen blanket for 2 h. The reaction was worked up by filtering off the K₂CO₃ and washing with CH₂Cl₂ to yield 437 mg (100%) of the title compound. IR (KBr) 3463.7, 3349.2, 3221.3, 1623.9, 1584.6, 1555.4, 1495.5, 1443.6, 1406.9, 1305.6, 1259.4, 1123.9,1051.7,896.7, 846.5, 760.1, 701.3, 632.1, 563.8 cm¹. ¹H NMR (400 MHz, CDCl₃) δ8.21 (s, 1H), 7.39-7.36 (m, 3H), 7.23-7.21 (m (overlapping), 2H), 6.61 (s, 1H). ¹³C NMR (100 MHz, CDCl₃) δ148.5, 139.4, 138.5, 130.7, 128.8, 128.4, 128.2, 128.1, 117.2, 106.3. HRMS Calc'd for 291.9848. Found: 291.9846.

2,5-Dinitro-4-phenylbromobenzene (9). 8 (373 mg, 1.28 mmol) in ethyl acetate (10 mL) was oxidized according to the general HOF oxidation procedure to yield 407 mg (99%) of a orange solid IR (KBr) 3446.7, 3090.4, 1542.8, 1461.1, 1443.1, 1347.3, 1257.7, 1114.6, 1076.2, 1051.8, 1021.0, 904.5, 842.5, 768.8, 743.7, 699.9, 551.0, 485.16 cm⁻¹. ¹H NMR (400 MHz, CDCl₃) δ8.16 (s, 1 H), 7.89 (s, 1 H), 7.47-7.45 (m, 3 H), 7.31-7.29 (m, 2 H). ¹³C NMR (100 MHz, CDCl₃) δ151.5, 150.6, 137.2, 134.4, 130.8, 130.1, 129.7, 128.9, 128.1, 114.1. HRMS Calc'd for 321.9589. Found: 321.9592.

2′, 4′-Dinitro-5′-phenyl-4-ethynylphenyl-1-thioacetylbenzene (2). 9 (147 mg, mmol), 4-ethynyl(thioacetyl)benzene (106 mg, 0.60 mmol), bis(dibenzylideneacetone)palladium (26 mg, 0.05 mmol), copper(I) iodide (9 mg, 0.05 mmol), triphenylphosphine (12 mg, 0.05 mmol), Hunig's base (0.16 mL) and THF (20 mL) were coupled according to the general coupling procedure. The reaction mixture was stirred and heated overnight at 45° C. Crude product was purified via column chromatography (silica, 3:1 dichloromethane:hexanes) to yield 75 mg of an orange solid (39%). IR (KBr) 2922.7, 2214.3, 1702.7, 1542.8, 1488.1, 1357.1, 1271.1, 1115.1, 1088.6, 956.0, 908.6, 829.9, 770.5, 707.0, 623.4 cm⁻¹. ¹H NMR (400 MHz, CDCl₃) δ8.16 (s, 1 H), 8.10 (s, 1 H), 7.63 (d, J=8.4, 2 H), 7.48-7.44 (m, 5 H), 7.36-7.33 (m, 2 H), 2.44 (s, 3 H). ¹³C NMR (100 MHz, CDCl₃) δ193.3, 151.2, 150.6, 136.8, 134.8, 134.7, 133.1, 130.8, 130.2, 130.1, 129.6, 128.6, 128.1, 122.9, 119.0, 99.8, 84.5, 30.8. HRMS Calc'd for 418.0623. Found: 418.0619.

2,5-Dibromo-1,4-dimethoxybenzene (11). In a 100 mL round bottom flask, 1,4-dimethoxybenzene (10.0 g, 72.4 mmol) was dissolved in glacial acetic acid (20 mL). A solution of bromine (7.42 mL, 145.0 mmol) in glacial acetic acid (7.5 mL) was added dropwise to the first solution at room temperature over 40 min. The resulting mixture was allowed to stir for 2 h. The crude product was washed with ice-cold water and ice-cold methanol to afford fine white crystals. The mother liquor was concentrated and cooled to afford more white crystals (15.9 g, 74% yield). Mp 136-138° C. (lit²¹ mp 144-145° C.). IR (KBr) 3091.9, 3022.1, 2968.8, 2944.4, 2842.8, 1694.9, 1494.2, 1475.6, 1436.5, 1358.2, 1275.0, 1211.8, 1185.0, 1065.4, 1021.9, 860.5, 760.4, 441.8 cm⁻¹. ¹H NMR (400 MHz, CDCl₃) δ7.13 (s, 2 H), 3.87 (s, 6 H). ¹³C NMR (100 MHz, CDCl₃) δ150.93, 117.53, 110.90, 57.43.

2,5-Di(ethynylphenyl)-1,4-dimethoxybenzene (12). 11 (8.745 g, 29.55 mmol), bis(triphenylphosphine)palladium dichloride (0.415 g, 0.591 mmol), copper(I) iodide (0.225 g, 1.182 mmol), triphenylphosphine (0.310 g, 1.182 mmol), THF (35 mL), Hünig's base (20.5 mL, 118 mmol), and phenylacetylene (7.8 mL, 70.92 mmol) were used following the general procedure for couplings. The solution was heated in a 65° C. oil bath for 3 d. Recrystallization from benzene afforded the desired product mp 175-177° C. (lit.¹⁶ 176-177° C.) (9.22 g, 92%). ¹H NMR (400 MHz, CDCl₃) δ7.57 (m, 4 H), 7.34 (m, 6H), 7.03 (s, 2H), 3.89 (s, 6 H). ¹³C NMR (100 MHz, CDCl₃) δ154.10, 131.89, 128.60, 128.50, 123.39, 115.86, 113.57, 95.23, 85.86, 56.66.

2,5-Di(ethynylphenyl)benzoquinone (13). 12 (0.300 g, 0.886 mmol) and THF (6 mL) were added to a 25 mL round bottom flask containing a stir bar. A solution of ceric ammonium nitrate (1.46 g, 2.658 mmol) in water (3 mL) was slowly added to the flask and allowed to stir for 15 min. Water was added and the organic materials were extracted with dichloromethane. Flash column chromatography (silica gel using 1:1 hexanes/dichloromethane as eluent) afforded the desired product (0.129 g, 47%). IR (KBr) 3047.5, 2203.0, 1716.2, 1655.3, 1568.3, 1215.4, 1100.6, 902.1, 757.6, 686.4 cm⁻¹. ¹H NMR (400 MHz, CDCl₃) □7.58 (dd, J=7.9, 1.5 Hz, 4 H), 7.38 (m, 6 H), 6.99 (s, 2 H). ¹³C NMR (100 MHz, CDCl₃) δ182.87, 136.55, 133.34, 132.83, 130.57, 128.97, 121.83, 105.26, 82.90. HRMS calc'd for C₂₂,H₁₂,O₂: 308.0837 Found: 308.0834.

2-Bromo-5-ethynylphenyl-1,4-dimethoxybenzene (14). 11 (2.96 g, 10.0 mmol), bis(dibenzylideneacetone)palladium (0.115 g, 0.20 mmol), copper(I) iodide (0.038 g, 0.20 mmol), triphenylphosphine (0.131 g, 0.50 mmol), THF (15 mL), Hünig's base (6.97 mL, 40.0 mmol) and phenylacetylene (1.21 mL, 11.0 mmol) were used following the general procedure for coupling. The tube was heated in a 50° C. oil bath for 18 h. Column chromatography (silica gel using 19:1 hexanes/diethyl ether as eluent) afforded the desired product, somewhat impure (approximately 15% impurities by NMR) in moderate yield (1.02 g, 32% yield). This was taken onto the next step in this impure form. ¹H NMR (400 MHz, CDCl₃) δ7.54 (m, 2 H), 7.33 (m, 3 H), 7.09 (s, 1 H), 7.02 (s, 1 H), 3.86 (s, 6 H).

1,4-Dimethoxy-2-ethynylphenyl-5-(trimethylsilylethynyl)benzene. 14 (1.0 g, 3.15 mmol), bis(dibenzylideneacetone)palladium (0.036 g, 0.063 mmol), copper(I) iodide (0.012 g, 0.063 mmol), triphenylphosphine (0.042 g, 0.16 mmol), THF (20 mL), Hünig's base (2.2 mL, 12.6 mmol), and trimethylsilylacetylene (0.89 mL, 6.3 mmol) were used following the general procedure for couplings. The tube was capped and heated in a 60° C. oil bath for 1 d. Flash column chromatography (silica gel using 24:1 hexanes/ethyl acetate as eluent) afforded the desired product slightly impure (0.83 g, 79% yield). ¹H NMR (400 MHz, CDCl₃) δ7.55 (m, 2 H), 7.32 (m, 3 H), 6.98 (s, 1 H), 6.95 (s, 1 H), 3.84 (s, 3 H), 3.83 (s, 3 H), 0.27 (s, 9 H).

1,4-Dimethoxy-2-ethynyl-5-(ethynylphenyl)benzene (15). 1,4-dimethoxy-2-ethynylphenyl-5-(trimethylsilylethynyl)benzene (0.830 g, 2.48 mmol), potassium carbonate (1.71 g, 12.4 mmol), methanol (50 mL), and dichloromethane (50 mL) were used following the general procedure for deprotection to afford the desired product (0.513 g, 79% yield). ¹H NMR (400 MHz, CDCl₃) δ7.55 (m, 2 H), 7.33 (m, 3 H), 7.00 (s, 1 H), 6.98 (s, 1 H), 3.87 (s, 3 H), 3.86 (s, 3 H), 3.39 (s, 1 H).

4,4′-Di(ethynylphenyl)-2′,5′-dimethoxy-1-benzenethioacetate (16). 15 (0.513 g, 1.96 mmol), bis(dibenzylideneacetone)palladium(0) (0.058 g, 0.10 mmol), copper(I) iodide (0.019 g, 0.10 mmol), triphenylphosphine (0.066 g, 0.25 mmol), THF (20 mL), Hünig's base (1.37 mL, 7.84 mmol), and 4-(thioacetyl)iodobenzene (0.608 g, 2.16 mmol) were used following the general procedure for couplings. The tube was capped and heated in a 55° C. oil bath for 3 d. Flash column chromatography (silica gel using dichoromethane as eluent) afforded the desired product slightly impure (0.621 g, 76% yield). ¹H NMR (400 MHz, CDCl₃) δ7.57 (m, 4 H), 7.38 (d, J=8.1 Hz, 2 H), 7.33 (m, 3 H), 7.03 (s, 1 H), 7.02 (s, 1 H), 3.874 (s, 3 H), 3.870 (s, 3 H), 2.40 (s, 3 H).

2-Ethynylphenyl-5-((4′-thioacetyl)ethynylphenyl)benzoquinone (17). 16 (0.050 g, 0.12 mmol), acetonitrile (5 mL), and THF (5 mL) were added to a 25 mL round bottom flask containing a stir bar. A solution of ceric ammonium nitrate (0.13 g, 0.24 mmol) in water (1 mL) was added in one portion. After stirring at room temperature for 30 min, another equivalent solution of ceric ammonium nitrate (0.13 g, 0.24 mmol) was added. After 20 additional min, the reaction was quenched by adding water (30 mL) to effect precipitation of an orange solid. Flash column chromatography (silica gel using dichloromethane as eluent) afforded the desired product (0.034 g, 74% yield). IR (KBr) 3053.0, 2924.3, 2852.6, 2205.4, 1703.4, 1652.7, 1568.8, 1483.7, 1442.2, 1354.8, 1221.3, 1105.4, 1089.4, 949.6, 920.1, 830.9, 758.2, 688.2, 620.6 cm⁻¹. ¹H NMR (400 MHz, CDCl₃) δ7.58 (m, 4 H), 7.42 (m, 2 H), 7.38 (m, 3 H), 6.98 (s, 1 H), 6.97 (s, 1 H), 2.42 (s, 3 H). ¹³C NMR (100 Mz, CDCl₃) δ193.22, 182.74, 182.67, 136.88, 136.51, 134.63, 133.34, 133.24, 132.99, 132.84, 130.94, 130.63, 128.99, 122.81, 121.80, 105.38, 103.99, 84.17, 82.92, 30.80. HRMS calc'd for C₂₄,H₁₄,O₃,S: 382.0664. Found: 382.0663.

1,4-Dimethoxy-2,5-bis(trimethylsilylethynyl)benzene. 11 (1.75 g, 5.91 mmol), bis(triphenylphosphine)palladium dichloride (0.207 g, 0.296 mmol), copper(I) iodide (0.113 g, 0.591 mmol), triphenylphosphine (0.155 g, 0.591 mmol), THF (20 mL), Hünig's base (4.1 mL, 23.64 mmol), and trimethylsilylacetylene (2.51 mL, 17.73 mmol) were used following the general procedure for couplings. The tube was capped and heated in a 55° C. oil bath for 2 d. Flash column chromatography (silica gel using 1:1 hexanes/dichloromethane as eluent) afforded the desired product (1.54 g, 79% yield). IR (KBr) 2957.0, 2898.2, 2851.2, 2829.0, 2149.1, 1496.8, 1464.1, 1449.1, 1388.2, 1283.7, 1249.0, 1223.6, 1203.1, 1172.4, 1039.6, 883.2, 841.3, 757.4, 714.9, 696.2, 626.4 cm⁻¹. ¹H NMR (400 MHz, CDCl₃) δ6.89 (s, 2 H), 3.81 (s, 6 H), 0.25 (s, 18 H) ¹³C NMR (100 MHz, CDCl₃) δ154.56, 116.59, 113.81, 101.22, 100.84, 56.83, 0.40. HRMS calc'd for C₁₈,H₂₆,O₂,Si₂: 330.1471, Found: 330.1468.

1,4-Dimethoxy-2,5-diethynylbenzene (18). 1,4-Dimethoxy-2,5-bis(trimethylsilylethynyl)benzene (1.50 g, 4.54 mmol), potassium carbonate (6.27 g, 45.4 mmol), methanol (50 mL), and dichloromethane (50 mL) were used following the general procedure for deprotection to give the desired product (0.829 g, 98%). ¹H NMR (400 MHz, CDCl₃) δ6.96 (s, 2 H), 3.84 (s, 6 H), 3.37 (s, 2 H).

2,5-Bis(4′-(thioacetyl)ethynylphenyl)-1,4-dimethoxybenzene (19). 18 (0.810 g, 4.35 mmol), bis(dibenzylideneacetone)palladium (0.253 g, 0.44 mmol), copper(I) iodide (0.084 g, 0.44 mmol), triphenylphosphine (0.115 g, 0.44 mmol), THF (30 mL), Hünig's base (4.5 mL, 26.1 mmol), and 4-(thioacetyl)iodobenzene²² (2.54 g, 9.14 mmol) were used following the general procedure for couplings. The solution was stirred in a 60° C. oil bath for 16 h. Crystallization from dichloromethane/hexanes afforded the desired product (1.81 g, 85%). IR (KBr) 3129.1, 3057.4, 3006.2, 2975.5, 2940.0, 2847.4, 2207.2, 1697.7, 1506.8, 1483.1, 1463.1, 1396.2, 1279.2, 1223.5, 1122.2, 1034.2, 949.5, 898.8, 825.5, 765.6, 616.8 cm⁻¹. ¹H NMR (400 MHz, CDCl₃) δ7.57 (dt, J=8.5, 1.9 Hz, 4 H), 7.39 (dt, J=8.5, 2.0 Hz, 4 H), 7.01 (s, 2 H), 3.89 (s, 6 H), 2.42 (s, 6H). ¹³C NMR (100 MHz, CDCl₃) δ193.85, 154.43, 134.58, 132.65, 128.64, 124.84, 116.08, 113.75, 94.76, 87.73, 56.91, 30.70. HRMS calc'd for C₂₈,H₂₂,O₄,S₂,: 486.0960 Found: 486.0956.

2,5-Bis(4′-(thioacetyl)ethynylphenyl)benzoquinone (20). 19 (0.050 g, 0.103 mmol), acetonitrile (5 mL), and THF (3 mL) were added to a 25 mL round bottom flask containing a stir bar. A solution of ceric ammonium nitrate (0.339 g, 0.618 mmol) in water (2 mL) was added in two portions at 30 min intervals. After stirring at room temperature for 3 h, the reaction was quenched by adding water to effect precipitation of an orange solid. Flash column chromatography (silica gel using dichloromethane as eluent) afforded the desired product (0.023 g, 49% yield). IR (KBr) 2922.2, 2847.4, 2203.4, 1694.9, 1660.1, 1569.9, 1351.8, 1212.3, 1119.7, 1084.6, 1013.2, 960.3, 826.8, 620.6 cm⁻¹. ¹H NMR (400 MHz, CDCl₃) δ7.60 (dt, J=8.3, 1.6 Hz, 4 H), 7.42 (dt, J=8.3, 1.6 Hz, 4 H), 7.00 (s, 2 H), 2.43 (s, 6 H). ¹³C NMR (100 MHz, CDCl₃) δ192.23, 182.61, 136,86, 134.64, 133.25, 133.07, 130.97, 122.78, 104.14, 84.08, 30.79. HRMS calc'd for C₂₆,H₁₆,O₄,S₂: 456.0500, Found: 456.0490.

2,5-Bis(4′-ethynylpyridyl)-1-nitrobenzene (22). To a solution of 2,5-dibromonitrobenzene (0.28 g, 0.997 mmol), bis(triphenylphosphine)palladium dichloride (0.07 g, 0.098 mmol), copper(I) iodide (0.019 g, 0.098 mmol), triphenylphosphine (0.106 g, 0.40 mmol) and K₂CO₃ (1.1 g, 7.96 mmol) in THF (4 mL) were added via a cannula 21 (0.377 g, 2.15 mmol) in THF (4 mL) and MeOH (2 mL). The mixture was heated at 64° C. for 20 h. The solvent was removed by rotary evaporation and the black residue was washed with aqueous K₂CO₃ and extracted with Et₂O. The combined organic layers were dried over Na₂SO₄, filtered, and the solvent evaporated in vacuo. Purification by flash chromatography (silica gel, hexane/AcOEt 70/30, 50/50, 20/80, 0/100) afforded 60 mg (24% yield) of the title compound as a yellow solid. Mp: 178-180° C. JR (KBr) 3414.0, 3036.7, 1616.0, 1589.4, 1538.1, 1519.9, 1407.9, 1345.7, 1271.1, 1214.1, 828.3 cm⁻¹. ¹H NMR (400 MHz, DMSO-d) δ8.69 (br s, 4 H), 8.44 (d, J=1.4 Hz, 1 H), 8.04 (1/2 ABqd, J=8.0, 1.4 Hz, 1 H), 7.99 (1/2 ABq, J=8.0 Hz, 1 H), 7.60 (d, J=5.8 Hz, 2 H), 7.57 (d, J=5.8 Hz, 2 H). ¹³C NMR (100 MHz, DMSO-d) δ150.21, 150.13, 149.42, 136.27, 135.36, 129.16, 129.11, 127.96, 125.50, 125.39, 123.25, 116.55, 94.98, 90.63, 90.59, 88.13. HRMS calc'd for C₂₀H₁₁N₃O₂: 325.0851, found: 325.0847.

1-Bromo-4-(4′-ethynylpyridyl)-3-nitrobenzene (23). To a solution of 2,5-dibromonitrobenzene (0.43 g, 1.53 mmol), bis(triphenylphosphine)palladium(II) dichloride (0.052 g, 0.074 mmol), copper(I) iodide (0.015 g, 0.078 mmol), triphenylphosphine (0.079 g, 0.30 mmol) and K₂CO₃ (0.83 g, 6.0 mmol) in THF (2 mL) were added via a cannula 21 (0.342 g, 1.95 mmol) in THF (4 mL) and MeOH (1.5 mL). The mixture was heated at 23° C. for 2 d. The solvent was removed by rotary evaporation and the residue was diluted with water and extracted with Et₂O. The combined organic layers were dried over Na₂SO₄, filtered, and the solvent evaporated in vacuo. Purification by flash chromatography (silica gel, hexane/AcOEt 90/10, 70/30, 50/50) afforded 330 mg (71% yield) of the title compound as an off-white solid. Mp: 166-171° C. IR (KBr) 3424.4, 3093.3, 1592.3, 1521.4, 1409.3, 1341.4, 1272.6 cm⁻¹. ¹H NMR (400 MHz, CDCl₃) δ8.68 (br s, 2 H), 8.29 (d, J=1.9 Hz, 1 H), 7.79 (dd, J=8.3, 2.0 Hz, 1 H), 7.44 (d, J=4.7 Hz, 2 H). ¹³C NMR (100 MHz, CDCl₃) δ149.96, 136.22, 135.69, 130.14, 128.08, 126.67, 125.65, 123.19, 116.48, 94.80, 87.81. HRMS calc'd for C₁₃H₇BrN₂O₂:303.9672, found: 303.9682.

5-Ethynylphenyl-2-(4′-ethynylpyridyl)-1-nitrobenzene (24). To a solution of 23 (88.8 mg, 0.293 mmol), bis(triphenylphosphine)palladium(II) dichloride (0.011 g, 0.016 mmol), copper(I) iodide (0.004 g, 0.021 mmol) and triphenylphosphine (0.008 g, 0.029 mmol) in THF (4 mL) were added Et₃N (0.25 mL, 1.76 mmol) and phenylacetylene (0.1 mL, 9.1 mmol). The mixture was stirred at 56° C. for 36 h. The solvent was evaporated in vacuo. The residue was diluted with water and extracted with Et₂O. The combined organic layers were dried over MgSO₄, filtered, and the solvent evaporated in vacuo. Purification by flash chromatography (silica gel, AcOEt/hexane 20/80) afforded 65 mg (69% yield) of the title compound as a yellow solid. Mp: 130-132° C. IR (KBr) 3445.3, 3046.3, 2203.5, 1548.5, 1529.1, 1399.9, 1341.6 cm⁻¹. ¹H NMR (400 MHz, CDCl₃) δ8.67 (br d, J=4.9 Hz, 2 H), 8.27 (d, J=1.5 Hz, 1 H), 7.76 (1/2 ABqd, J=8.0, 1.6 Hz, 1 H), 7.72 (1/2 ABqd, J=8.0, 0.5 Hz, 1 H), 7.56 (m, 2 H), 7.45 (dd, J=5.9, 1.7 Hz, 2 H), 7.40 (m, 3 H). ¹³C NMR (100 MHz, CDCl₃) δ149.58, 135.39, 134.65, 131.81, 129.34, 128.54, 127.67, 125.32, 121.85, 116.66, 95.30, 94.30, 88.52, 86.63. HRMS calc'd for C₂₁H₁₂N₂O₂: 324.0899, found: 324.0895.

1-Bromo-4-ethynylphenyl-3-nitrobenzene (25). To a solution of 2,5-dibromonitrobenzene (0.937 g, 3.34 mmol), bis(dibenzylideneacetone)palladium (0.095 g, 0.166 mmol), copper(I) iodide (0.032 g, 0.168 mmol) and triphenylphosphine (0.173 g, 0.66 mmol) in THF (4 mL) were added Et₃N (1 mL, 7.2 mmol) and phenylacetylene (0.5 mL, 4.56 mmol). The mixture was stirred at 23° C. for 48 h. The mixture was washed with a saturated solution of NH₄Cl and then extracted with Et₂O. The combined organic layers were dried over Na₂SO₄, filtered, and the solvent evaporated in vacuo. Purification by flash chromatography (silica gel, CH₂Cl₂/hexane 1/8) afforded 0.48 g (47% yield) of the title compound as a yellow solid. Mp: 58-74° C. IR (KBr) 3421.9, 3085.5, 2213.4, 1595.7, 1545.9, 1521.3, 1336.5, 1269.2 cm⁻¹. ¹H NMR (400 MHz, CDCl₃) δ8.23 (d, J=1.9 Hz, 1 H), 7.72 (dd, J=8.3 Hz, 2.0, 1 H), 7.59 (m, 3 H), 7.40 (m, 3 H). ¹³C NMR (100 MHz, CDCl₃) δ149.71, 135.91, 135.45, 131.99, 129.44, 128.46, 127.78, 122.03, 121.75, 117.69, 98.43, 84.00. HRMS calc'd for C₁₄H₈NO₂Br: 302.9720, found: 302.9725.

2-Ethynylphenyl-5-(4′-ethynylpyridyl)-1-nitrobenzene (26). To a solution of 25 (0.306 g, 1.01 mmol), K₂CO₃ (0.713 g, 5.16 mmol), bis(triphenylphosphine)palladium dichloride (0.035 g, 0.05 mmol), copper(I) iodide (0.009 g, 0.047 mmol) and triphenylphosphine (0.052 g, 0.198 mmol) in THF (2 mL) were added via a cannula 21 (0.217 g, 1.24 mmol) in THF (2 mL) and MeOH (1 mL). The mixture was heated at 60° C. for 18 h. The solvent was removed by rotary evaporation and the brown residue was diluted with water and extracted with Et₂O. The combined organic layers were dried over Na₂SO₄, filtered, and the solvent evaporated in vacuo. Purification by flash chromatography (silica gel, AcOEt/hexane 20/80, 40/60) afforded 260 mg (79% yield) of the title compound as a yellow solid. Mp: 144-146° C. IR (KBr) 3442.3, 3053.0, 2209.4, 1631.3, 1584.8, 1524.7, 1404.3, 1344.7, 1269.0, 826.4, 755.2, 686.6 cm⁻¹. ¹H NMR (400 MHz, CDCl₃) δ8.67 (dd, J=4.4, 1.6 Hz, 2 H), 8.27 (br s, 1 H), 7.74 (m, 2 H), 7.63 (d, J=1.8 Hz, 1 H), 7.60 (m, 1 H), 7.42 (m, 5 H). ¹³C NMR (100 MHz, CDCl₃) δ149.99, 135.41, 134.65, 132.14, 130.19, 129.61, 128.54, 127.95, 125.50, 122.68, 122.06, 119.15, 99.67, 90.83, 90.27, 84.62. HRMS calc'd for C₂₁H₁₂N₂O₂: 324.0899, found: 324.0897.

2,5-Bis(trimethylsilylethynyl)-4-nitroacetanilide (27). To a solution of 6 (0.78 g, 2.3 mmol), bis(dibenzylideneacetone)palladium (0.068 g, 0.118 mmol), copper(I) iodide (0.023 g, 0.012 mmol), triphenylphosphine (0.123 g, 0.47 mmol) in THF (8 mL) were added Et₃N (1 mL, 7.2 mmol) and trimethylsilylacetylene (1 mL, 7.0 mmol). The mixture was heated at 67° C. for 48 h. The solvent was removed by rotary evaporation and the brown residue was diluted with water and extracted with Et₂O. The combined organic phases were dried over Na₂SO₄, filtered, and the solvent evaporated in vacuo. Purification by flash chromatography (silica gel, CH₂Cl₂/ hexane 35/65) afforded 410 mg (47% yield) of the title compound as an off-white solid. Mp: 162-164° C. IR (KBr) 3372.9, 2962.9, 2146.0, 1727.2, 1611.2, 1544.9, 1501.5, 1457.1, 1404.3, 1338.2, 1250.6, 1222.3, 881.9 cm⁻¹. ¹H NMR (400 MHz, CDCl₃) δ8.75 (s, 1 H), 8.15 (s, 1 H), 8.10 (br s, 1 H), 2.27 (s, 3 H), 0.33 (s, 9 H), 0.28 (s, 9 H). ¹³C NMR (100 MHz, CDCl₃) δ168.21, 144.19, 142.41, 128.11, 123.82, 120.18, 111.52, 106.66, 106.16, 99.50, 97.44, 24.90, −0.31, −0.46. HRMS calc'd for C₁₈H₂₄N₂O₃Si₂: 372.1326, found: 372.1326.

2,5-Bis(4′-ethynylpyridyl)-4-nitroaniline (28). To a solution of 27 (0.056 g, 0.15 mmol), 4-iodopyridine (0.08 g, 0.39 mmol), K₂CO₃ (0.17 g, 1.2 mmol), bis(triphenylphosphine)palladium(II) dichloride (0.01 g, 0.015 mmol), copper(I) iodide (0.004 g, 0.021 mmol) and triphenylphosphine (0.016 g, 0.061 mmol) in THF (4 mL) was added MeOH (1 mL). The mixture was heated at 60° C. for 50 h. The solvent was removed by rotary evaporation and the brown residue was diluted with water and extracted with AcOEt. The combined organic phases were dried over Na₂SO₄, filtered, and the solvent evaporated in vacuo. Purification by flash chromatography (silica gel, AcOEt) afforded 8 mg (16% yield) of the title compound as a yellow solid. Mp: 154-160° C. IR (KBr) 3730.2, 3438.6, 2204.8, 1592.4, 1541.1, 1409.8, 1308.5, 1249.9, 818.8 cm⁻¹. ¹H NMR (400 MHz, CDCl₃) δ8.67 (dd, J=4.4, 1.7 Hz, 2 H), 8.65 (dd, J=4.5, 1.7 Hz 2 H), 8.34 (s, 1 H), 7.44 (dd, J=4.5, 1.7 Hz, 2 H), 7.40 (dd, J=4,4, 1.6 Hz, 2 H), 6.99 (s, 1 H), 5.03 (br s, 2 H). ¹³C NMR (100 MHz, CDCl₃) δ151.26, 150.03, 149.90, 139.56, 130.71, 130.52, 130.00, 125.65, 125.33, 120.33, 118.52, 106.57, 94.67, 94.19, 89.55, 87.27. HRMS calc'd for C₂₀H₁₂N₄O₂: 340.0960, found: 340.0958.

2-Amino-4-(4′-ethynylpyridyl)-5-nitrobromobenzene (29). To a solution of 6 (0.877 g, 8.84 mmol), K₂CO₃ (1.08 g, 7.81 mmol), bis(triphenylphosphine)palladium dichloride (0.054 g, 0.077 mmol), copper(I) iodide (0.025 g, 0.13 mmol) and triphenylphosphine (0.068 g, 0.26 mnmol) in THF (4 mL) were added via a cannula 21 (0.404 g, 2.30 mmol) in THF (8 mL) and MeOH (3 mL). The mixture was stirred at 23° C. for 1 d. The solvent was evaporated in vacuo. The residue was diluted with water and extracted with AcOEt. The combined organic phases were dried over MgSO₄, filtered and the solvent evaporated in vacuo. Purification by flash chromatography (silica gel, AcOEt/hexane 40/60 50/50) afforded 290 mg (39% yield) of the title compound as a yellow solid. Mp: 226-228° C. IR (KBr) 3385.4, 3297.7, 3171.3, 1646.8, 1591.7, 1556.9, 1471.3, 1297.8 cm⁻¹. ¹H NMR (400 MHz, DMSO-d) δ8.66 (br d, J=3.8 Hz, 2 H), 8.32 (d, J=1.3 Hz, 1 H), 7.53 (br d, J=4.5 Hz, 2 H), 7.06 (d, J=1.3 Hz, 1 H), 6.94 (br s, 2 H). ¹³C NMR (100 MHz, DMSO-d) δ151.33, 150.12, 136.44, 130.70, 129.64, 125.32, 118.13, 117.73, 106.02, 91.85, 89.72. HRMS calc'd for C₁₃H₈BrN₃O₂: 316.9800, found: 316.9801.

4-Amino-2-(4′-ethynylpyridyl)-1-nitro-5-(trimethylsilylethynyl)benzene. To a solution of 29 (0.310 g, 0.975 mmol), bis(triphenylphosphine) palladium dichloride (0.035 g, 0.05 mmol), copper(I) iodide (0.011 g, 0.05 mmol) and triphenylphosphine (0.026 g, 0.10 mmol) in THF (10 mL) were added Et₃N (0.9 mL, 6.5 mmol) and trimethylsilylacetylene (0.2 mL, 1.4 mmol). The mixture was stirred at 60° C. for 2 d. The solvent was evaporated in vacuo. The residue was diluted with water and extracted with AcOEt. The combined organic phases were dried over MgSO₄, filtered, and the solvent evaporated in vacuto. Purification by flash chromatography (silica gel, Et₂O) afforded 160 mg (49% yield) of the title compound as a yellow solid. Mp: 145-150° C. IR (KBr) 3451.9, 3379.1, 2960.5, 2149.5, 1620.4, 1597.9, 1545.5, 1512.2, 1317.0 cm⁻¹. ¹H NMR (400 MHz, CDCl₃) δ8.65 (dd, J=4.6, 1.5 Hz, 2 H), 8.25 (s, 1 H), 7.44 (dd, J=4.3, 1.5 Hz, 2 H), 6.93 (s, 1 H), 4.90 (s, 2 H), 0.30 (s, 9 H). ¹³C NMR (100 MHz, CDCl₃) δ151.44, 149.90, 139.35, 130.65, 130.43, 125.65, 119.56, 118.06, 107.93, 104.28, 98.37, 93.70, 89.79, −0.15. HRMS calc'd for C₁₈H₁₇N₃O₂Si: 335.1090, found: 335.1089.

4-Amino-5-ethynyl-2-(4′-ethynylpyridyl)-1-nitrobenzene. (30). To a solution of 4-Amino-2-(4′-ethynylpyridyl)-1-nitro-5-(trimethylsilylethynyl)benzene (160 mg, 0.477 mmol) in MeOH (15 mL) and CH₂Cl₂ (15 mL) was added K₂CO₃ (0.66 g, 4.77 mmol). The solution was stirred at 23° C. for 2 h. The reaction mixture was diluted with water and extracted with AcOEt. The combined organic layers were dried over MgSO₄, filtered, and the solvent evaporated in vacuo. The reaction afforded 0.11 g (88% yield) of the title compound as a yellow solid. The product was too unstable to attain its complete characterization data. ¹H NMR (400 MHz, DMSO-d) δ8.67 (dd, J=4.5, 1.6 Hz, 2 H), 8.12 (s, 1 H), 7.53 (dd, J=4.5, 1.6 Hz, 2 H), 7.03 (s, 1 H), 6.97 (br s, 2H), 4.70 (s, 1H).

4-Amino-2-(4′-ethynylpyridyl)-5-(4′-thioacetylphenylethynyl)-1-nitrobenzene (31). To a solution of 30 (0.110 g, 0.418 mmol), 4-thioacetyliodobenzene¹⁰ (0.124 g, 0.446 mmol), bis(triphenylphosphine)palladium(II) dichloride (0.015 g, 0.021 mmol), copper(I) iodide (0.004 g, 0.021 mmol) and triphenylphosphine (0.014 g, 0.053 mmol) in THF (13 mL) was added Et₃N (0.4 mL, 2.9 mmol). The mixture was stirred at 50° C. for 2 d. The reaction was checked by TLC (AcOEt/hex 75/25). More bis(triphenylphosphine)palladium dichloride (0.014 g, 0.020 mmol), copper(I) iodide (0.035 g, 0.018 mmol) and triphenylphosphine (0.085 g, 0.324 mmol) were added and the reaction was stirred at 60° C. for 1 d. The solvent was evaporated in vacuo. The residue was diluted with water and extracted with AcOEt. The combined organic layers were dried over MgSO₄, filtered, and the solvent evaporated in vacuo. Purification by flash chromatography (silica gel, AcOEt/hex 66/33) afforded 130 mg (75% yield) of the title compound as a yellow solid. Mp: 185-188° C. IR (KBr) 3438.2, 3195.9, 2922.4, 1695.4, 1627.7, 1596.5, 1545.1, 1514.8, 1477.2, 1402.8, 1316.4, 1249.9 cm⁻¹. ¹H NMR (400 MHz, DMSO-d) δ8.68 (br d, J=4.0 Hz, 2 H), 8.23 (s, 1 H), 7.79 (d, J=8.1 Hz, 2 H), 7.54 (d, J=5.0 Hz, 2 H), 7.49 (d, J=8.0 Hz, 2 H), 7.13 (br s, 2 H), 7.06 (s, 1 H), 2.46 (s, 3 H). ¹³C NMR (100 MHz, DMSO-d) δ192.98, 153.79, 150.13, 136.28, 134.31, 132.32, 130.69, 129.67, 128.66, 125.34, 123.05, 118.70, 118.26, 105.43, 95.72, 92.51, 90.12, 85.54, 30.32. HRMS calc'd for C₂₃H₁₅N₃O₃S: 413.0834, found: 413.0940.

2-(4′-Ethynylpyridyl)-4-nitro-5-phenylaniline (32). To a solution of 7 (80.5 mg, 0.241 mmol), K₂CO₃ (0.151 g, 1.09 mmol), bis(triphenylphosphine)palladium(II) dichloride (0.009 g, 0.014 mmol), copper(I) iodide (0.003 g, 0.014 mmol) and triphenylphosphine (0.014 g, 0.053 mmol) in THF (2 mL) were added via a cannula 1 (0.053 g, 0.3 mmol) in THF (2 mL) and MeOH (1 mL). The mixture was heated to 70° C. for 3 d. The solvent was removed by rotary evaporation and the brown residue was diluted with water and extracted with Et₂O. The combined organic layers were dried over Na₂SO₄, filtered and the solvent evaporated in vacuo. Purification by flash chromatography (silica gel, AcOEt/hex 30/70) afforded 60 mg (79% yield) of the title compound as a yellow solid. Mp: 187-190° C. IR (KBr) 3410.2, 3323.4, 3212.1, 2215.1, 1627.6, 1592.4, 1548.4, 1511.7, 1410.5, 1331.9 cm⁻¹. ¹H NMR (400 MHz, CDCl₃) δ8.64 (br d, J=4.8, 2 H), 8.16 (s, 1 H), 7.39 (m, 5 H), 7.27 (m, 2 H), 6.62 (s, 1 H), 5.03 (br s, 2 H). ¹³C NMR (100 MHz, CDCl₃) δ151.23, 149.82, 140.65, 138.82, 138.19, 130.49, 128.36, 128.06, 127.52, 125.34, 116.41, 104.85, 93.24, 87.89. HRMS calc'd for C₁₉H₁₃N₃O₂: 315.1008, found: 315.1011.

1-Bromo-4-(4′-ethynyl)pyridine-3-nitrobenzene (34). To a solution of 33¹ (0.84 g 2.34 mmol), bis(triphenylphosphine)palladium dichloride (0.083 g, 0.117 mmol), copper(I) iodide (0.022 g, 0.117 mmol), K₂CO₃ (1.94 g, 14.04 mmol) in THF (4 mL) were added 21 (0.451 g, 2.57 mmol) in THF (12 mL) via a cannula and MeOH (4 mL). The mixture was heated to 55° C. for 14 h. The solvent was removed by rotary evaporation and the residue was diluted with water, washed with brine and extracted with AcOEt. The combined organic phases were dried over MgSO₄, filtered and the solvent evaporated in vacuo. Purification by flash chromatography (silica gel, AcOEt) afforded 271 mg (34% yield) of the title compound as a yellow solid. Mp: 224-229° C. IR (KBr) 3451.7, 3351.1, 3202.6, 2206.4, 1622.9, 1588.4, 1539.0, 1474.4, 1306.7, 1249.8 cm⁻. ¹H NMR (400 MHz, DMSO-d) δ8.64 (d, J=5.7 Hz, 2 H), 8.25 (s, 1 H), 7.67 (dd, J=4.5, 1.5 Hz, 2 H), 7.59 (m, 2 H), 7.47 (m, 3 H), 7.15 (br s, 1 H), 7.03 (s, 1 H). ¹³C NMR (100 MHz, DMSO-d) δ153.97, 149.83, 136.31, 131.67, 131.17, 130.01, 129.69, 128.99, 125.45, 121.78, 120.40, 118.06, 103.92, 96.13, 93.41, 88.37, 86.25. HRMS calc'd for C₂₁H₁₃N₃O₂: 339.1008, found: 339.1004.

1-Bromo-3-nitro-4-(4-aminophenylethynyl)benzene (36). 1,4-Dibromo-2-nitrobenzene (5.62 g, 20.0 mmol), bis(triphenylphosphine)palladium dichloride (0.140 g, 0.20 mmol), copper(I) iodide (0.038 g, 0.20 mmol), triethylamine (10.0 mL), THF (10 mL) and 35 (1.170 g, 10.0 mmol) were used following the general procedure for couplings. The reaction mixture was stirred at room temperature for 4 h. After solvent removal in vacuo, the residue was chromatographed on a column of silica (dichloromethane as eluent) to give a mixture of the desired product along with its regioisomer as a red solid. The desired product was isolated from the mixture by a two-fold recrystallization from dichloromethane/hexanes as fine bright red needles (1.561 g, 49% yield). Mp 147-149° C. IR (KBr) 3457, 3367, 2194, 1623, 1593, 1513, 1550, 1334, 1273, 1136, 834, 817, 528 cm⁻¹. ¹H NMR (400 MHz, CDCl₃) □8.21 (d, J=2.0 Hz), 7.67 (dd, J=8.4, 2.0 Hz), 7.51 (d, J=8.4 Hz), 7.96 (m, AA′ part of AA′XX′ pattern, J=8.2, 2.7, 1.9, 0.4 Hz, 2 H), 7.93 (m, XX′ part of AA′XX′ pattern, J=8.2, 2.7, 1.9, 0.4 Hz, 2 H), 3.39 (s, 2 H). ¹³C NMR (100 MHz, CDCl₃) □149.27, 147.85, 135.82, 135.12, 133.71, 127.73, 120.62, 118.59, 114.63, 111.09, 100.24, 82.86. HRMS calc'd for C₁₄H₉N₂BrO₂: 315.9848, found: 315.9845.

4-(2-Nitro-4-phenylethynylphenylethynyl)aniline (37). 36 (0.697 g, 2.20 mmol), bis(triphenylphosphine)palladium dichloride (0.062 g, 0.088 mmol), copper(I) iodide (0.0084 g, 0.044 mmol), triethylamine (10.0 mL) and ethynylbenzene (0.306 g, 3.00 mmol) were used following the general procedure for couplings. The reaction mixture was stirred at 80° C. for 2 h. After solvent removal in vacuo, the residue was chromatographed on a column of silica with dichloromethane to give red needles of the desired product (0.72 g, 97% yield) Mp 166-168° C. IR (KBr) 3454, 3381, 3360, 2177, 2197, 1594, 1623, 1539, 1520, 1299, 1342, 1133, 829, 758, 690, 527 cm⁻¹. ¹H NMR (400 MHz, CDCl₃) □8.20 (dd, J=1.6, 0.3 Hz), 7.66 (dd, J=8.2, 1.6, Hz), 7.61 (d, J=8.1 Hz), 7.52-7.57 (m, 2 H), 7.36-7.43 (m, 5 H), 3.94 (s, 2 H). ¹³C NMR (100 MHz, CDCl₃) □148.93, 147.81, 135.12, 134.04, 133.76, 131.74, 129.04, 128.49, 127.59, 122.97, 122.18, 118.95, 114.64, 111.29, 100.75, 93.03, 87.05, 83.71. HRMS calc'd for C₂₂H₁₄N₂O₂: 338.1055, found: 338.1058.

4-(2-Nitro-4-phenylethynylphenylethynyl)benzenediazonium tetrafluoroborate (38). Following the general diazotization procedure 37 (0.0845 g, 0.250 mmol) was treated with NOBF₄ (0.0322 g, 0.275 mmol) in acetonitrile (2 mL)/sulfolane (2 mL). The product was precipitated with ether (12 mL) as dark orange scales. The salt was washed with ether and reprecipitated from DMSO (0.5 mL) and CH₂Cl₂ (20 mL) as lustrous dark orange plates (0.0885 g, 81% yield). IR (KBr) 3103, 2279, 2209, 1576, 1345, 1540, 1084, 841, 764 cm⁻¹. ¹H NMR (400 MHz, CDCl₃/DMSO-d₆, line width of about 1.9 Hz was observed) □8.78 (d, J=8.9 Hz, 2 H), 8.30 (s, 1 H), 8.03 (d, J=8.9 Hz, 2 H), 7.85-7.92 (m, 2 H), 7.57-7.60 (m, 2 H), 7.42-7.44 (m, 3H). ¹³C NMR (100 MHz, CDCl₃/DMSO-d₆) □149.00, 135.46, 134.85, 134.15, 133.31, 132.84, 1.34, 129.13, 128.21, 127.15, 125.66, 121.06, 114.81, 114.25, 94.57, 94.42, 94.11, 86.29.

4-(3-Nitro-4-phenylethynylphenylethynyl)aniline (39). 25 (1.208 g, 4.0 mmol), bis(triphenylphosphine)palladium dichloride (0.070 g, 0.10 mmol), copper(I) iodide (0.019 g, 0.10 mmol), triethylamine (6.0 mL), THF (6.0 mL) and 35 (0.479 g, 4.10 mmol) were used following the general procedure for couplings. The reaction mixture was stirred at room temperature for 15 h. After solvent removal in vacuo, the residue was chromatographed on a short column of silica with dichloromethane/hexanes (1:1) to afford the desired product as an orange solid (0.560 g, 44% yield): mp 175-177° C. IR (KBr) 3303, 2985, 1696, 1587, 1522, 1406, 1314, 1243, 1153, 1060, 839, 757, 692 cm⁻¹. ¹H NMR (400 MHz, CDCl₃) □8.16 (t, J=1.0 Hz, 1H), 7.64 (d, J=1.0 Hz, 2H), 7.58-7.61 (m, 2H), 7.34-7.40 (m, 3H), 7.35 (m, AA′ part of AA′XX′ pattern, J=8.0, 2.5, 2.0, 0.4 Hz, 2 H), 6.65 (m, XX′ part of AA′XX′ pattern, J=8.0, 2.5, 2.0, 0.4 Hz, 2 H), 3.91 (s, 2H). ¹³C NMR (100 MHz, CDCl₃) 149.4, 147.5, 134.9, 134.3, 133.3, 132.0, 129.3, 128.5, 127.1, 124.9, 122.3, 117.1, 114.7, 11.1, 98.4, 94.9, 85.3, 85.0. HRMS calc'd for C₂₂H₁₄N₂O₂: 338.1055, found: 338.1059.

4-(3-Nitro-4-phenylethynylphenylethynyl)benzenediazonium tetrafluoroborate (40). Following the general diazotization procedure, 39 (0.0676 g, 0.200 mmol) was treated with NOBF₄ (0.025 g, 0.210 mmol) in acetonitrile (2 mL)/sulfolane (2 mL). The product was precipitated with ether (20 mL) as fine orange-red crystals. The salt was washed with ether and reprecipitated from DMSO (0.6 mL) and CH₂Cl₂ (10 mL) as heavy lustrous red plates (0.0676 g, 77% yield). IR (KBr) 3101, 2279, 2209, 1576, 1540, 1346, 1083, 1034, 840, 764 cm⁻¹. ¹H NMR (400 MHz, CDCl₃/DMSO-d₆) □7.94 (m, AA′ part of AA′XX′ pattern, J=8.7, 2.4, 1.7, 0.4 Hz, 2 H), 7.82 (dd, J=1.7, 0.4 Hz, 1 H), 7.49 (m, XX′ part of AA′ XX′ pattern, J=8.7, 2.4, 1.7, 0.4 Hz, 2 H), 7.62 (dd, J=8.1, 1.7 Hz, 1 H), 7.56 (dd, J=8.1, 0.4 Hz, 1 H), 7.07 (m, AA′ part of AA′XX′Y pattern, J=7.8, 7.6, 1.8, 1.3, 1.3, 0.6 Hz, 2 H), 6.94 (tt, J=7.6, 1.3 Hz, 1 H), 6.91 (m, YY′ part of AA′XX′Y pattern, J=7.8, 7.6, 1.8, 1.3, 1.3, 0.6 Hz, 2 H). ¹³C NMR (100 MHz, CDCl₃/DMSO-d₆) □137.24, 136.97, 136.23, 135.40, 133.72, 133.00, 131.08, 129.96, 129.48, 122.81, 122.75, 120.68, 114.12, 100.47, 98.81, 91.04, 85.57.

4-(2,5-Dinitro-4-(4-amninophenylethynyl)phenylethynyl)aniline (42). 1,4-Dibromo-2,5-dinitrobenzene¹² (0.977 g, 3.0 mmol), bis(triphenylphosphine)palladium dichloride (0.042 g, 0.06 mmol), copper(I) iodide (0.011 g, 0.06 mmol), triethylamine (5.0 mL), THF (5.0 mL) and 4-ethynylaniline (0.468 g, 4.00 mmol) were used following the general procedure for couplings. The reaction mixture was stirred at room temperature for 12 h. After solvent removal in vacuo, the residue was sonicated with dichloromethane (10 mL) and filtered. The filter cake was washed 5×with dichloromethane (10 mL) and dried in vacuo to afford dark purple crystals of the diarnine 42 (0.432 g, 36% yield). Mp>270° C. IR (KBr) 3494, 3387, 2184, 1600, 1400, 1523, 1537, 1308, 1337, 1251, 1136 cm⁻¹. ¹H NMR (400 MHz, DMSO-d₆) □8.37 (s, 2 H), 7.27-7.29 (m, 2 H), 6.59-6.61 (m, 2 H), 5.93 (br s, 4 H). ¹³C NMR (100 MHz, DMSO-d₆) □151.18, 149.89, 133.67, 129.43, 116.95, 113.66, 106.10, 103.45, 82.23. HRMS calc'd for C₂₂H₁₄N₄O₄: 398.1015, found 398.1018.

4-(2,5-Dinitro-4-(4-diazoniophenylethynyl)phenylethynyl)benzenediazonium tetrafluoroborate (43). Following the general diazotization procedure 42 (0.199 g, 0.500 mmol) was treated with NOBF₄ (0.128 g, 1.10 mmol) in acetonitrile (5.0 mL)/sulfolane (5.0 mL). The product was precipitated with ether (20 mL). The salt was washed with ether and reprecipitated from DMSO and CH₂Cl₂ as light-sensitive yellow crystals (0.215 g, 72% yield). IR (KBr) 3107, 2291, 1579, 1546, 1342, 1078, 830 cm⁻¹. ¹H NMR (400 MHz, CDCl₃/DMSO-d₆) □8.85 (s, 2H), 8.79 (d, J=9 Hz, 2 H), 8.20 (d, J=9 Hz, 2 H). ¹³C NMR (100 MHz, CDCl₃/DMSO-d₆) □150.60, 133.93, 133.83, 133.14, 132.40, 131.75, 117.62, 116.32, 96.91, 91.51.

Many oligo(phenylene ethynylene)s containing reversibly reducible functionalities based on quinone and nitro cores have been synthesized. These molecules have methods of attachment to a metal surface ranging from the standard protected thiol groups to the novel diazonium and pyridyl linkages.

### Example 2

Molecular Electronic Devices Containing Pyridine Units

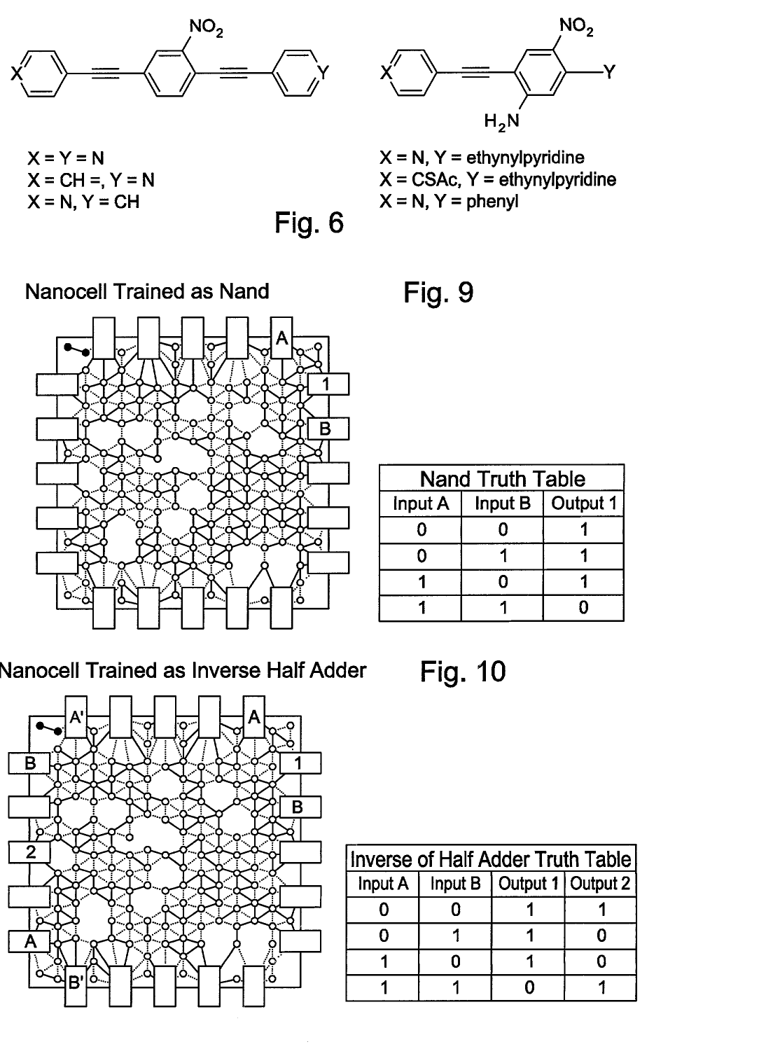

FIG. 6 shows the two groups of potential molecular devices that have been synthesized. The first group has a nitro functionality on the internal phenyl ring, which was designed to retain electrons so that the molecule could work as a memory element.

The second group has a nitro and an amino group, which have been shown to work similarly albeit at lower temperature.

The potential molecular devices 2 and 4 were envisioned to have two pyridyl terminal groups so that they could serve as cross-linkers for gold connections.

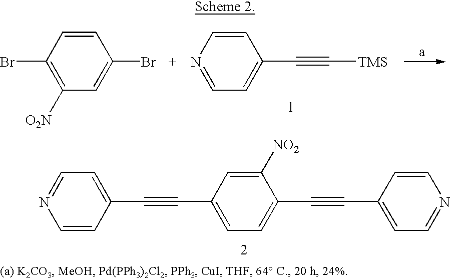

Scheme 2 outlines the synthesis of 2 from 2,5-dibromonitrobenzene. 1 was easily prepared via Sonogashira⁶ coupling of 4-iodopyridine⁷ and trimethylsilyl acetylene (99%). Potassium carbonate is used as a base for the in situ removal of the TMS protecting group and for the coupling, as the free alkyne decomposes after a few hours. Attempts to perform the reaction at room temperature gave mostly the bis(ethynylpyridine) and coupling at one site of the aryl dibromide.

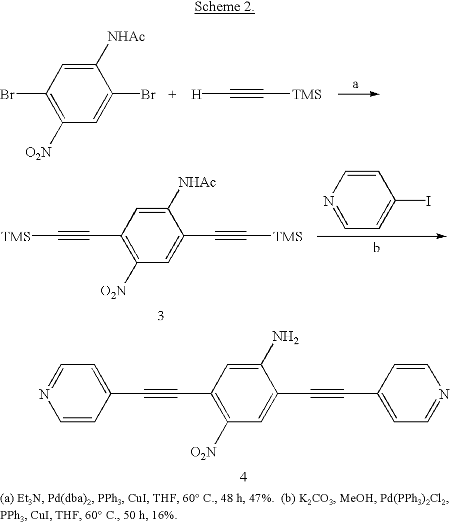

Compound 4 resembles 2, but has a nitroaniline core instead of a nitro core. Unlike the potential molecular device 2, the synthesis of 4 (Scheme 2) commenced with the coupling of 2,5-dibromo-4-nitroacetanilide⁹ with trimethylsilylacetylene to give 3, which was then coupled with 4-iodopyridine in low yield. The low yield of the coupling reactions could be due to cyclization between the nitro and the alkyne unit.

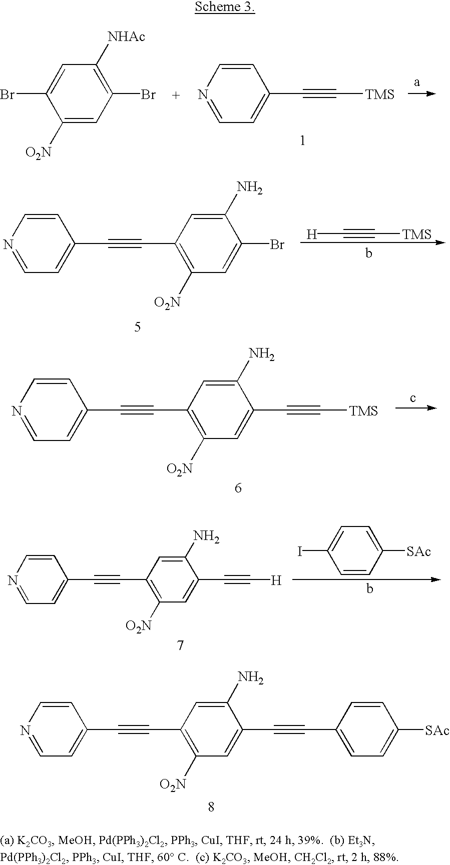

The synthesis of 8 is shown in Scheme 3. 8 has a protected benzenethiol terminal group, which can bind to a gold surface. The other end of the molecule has a pyridyl group, which could possibly serve as a better top-layer linker than the phenyl group. 8 was synthesized by coupling the 2,5-dibromo-4-nitroacetanilide with 1 in a moderate yield to afford compound 5. Compound 5 was then coupled with trimethylsilylacetylene to afford 6 in 49% yield, which was deprotected with potassium carbonate to give 7. The last step of this synthesis was the coupling with 4-thioacetyliodobenzene, which afforded the potential device 8 in good yield (75%).

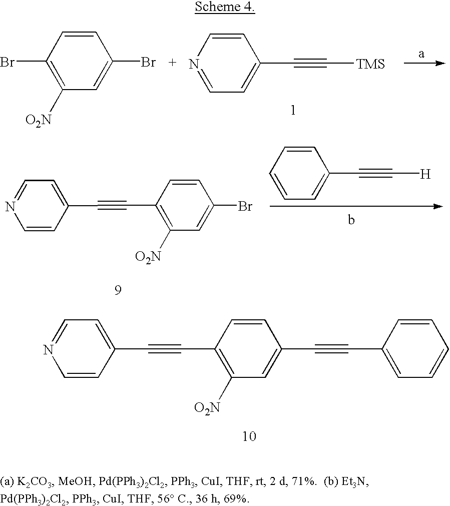

10 and 12 were synthesized to study the importance of the position of the nitro group relative to the “alligator clip” during the self-assembly. 10, which has the nitro group oriented toward the pyridyl group (Scheme 4), was synthesized by first coupling 1 with 2,5-dibromonitrobenzene, with in situ removal of the TMS group to give 9 in good yield. Coupling of 9 with phenylacetylene afforded 10.

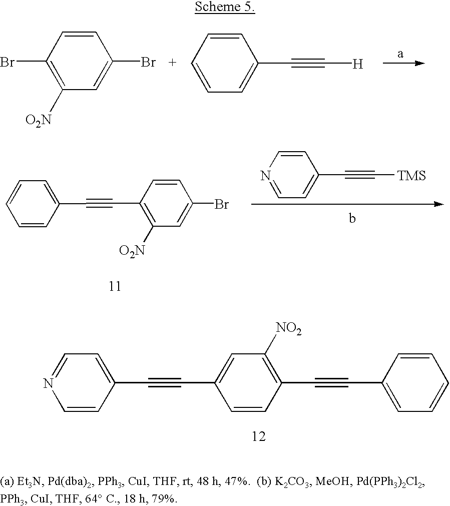

The synthesis of 12 (Scheme 5), which has the nitro group pointing away from the pyridyl group, resembles the approach used for 10 except that the steps are reversed. In this case, the phenylacetylene was first coupled to 2,5-dibromonitrobenzene to give 11 in a moderate yield. 1 was then coupled to 11 to afford 12 in good yield.

In order to conduct electrons with minimal inhibition, these organic oligomers preferably have all their phenyl rings in the same plane. If the terminal phenylethynyl group is replaced by a phenyl group, the molecule becomes slightly twisted. To study the effect of this rotational barrier, 14 was synthesized. The Suzuki coupling of 2,5-dibromo-4-nitroacetanilide with phenyl boronic acid was used to synthesize compound 13 (Scheme 6), which was then coupled to 4-(trimethylsilylethynyl)pyridine (1) to afford 14.

The structures of compounds 2, 4, 8, 10, 12 and 14 were confirmed by IR, ¹H NMR, ¹³C NMR and MS.

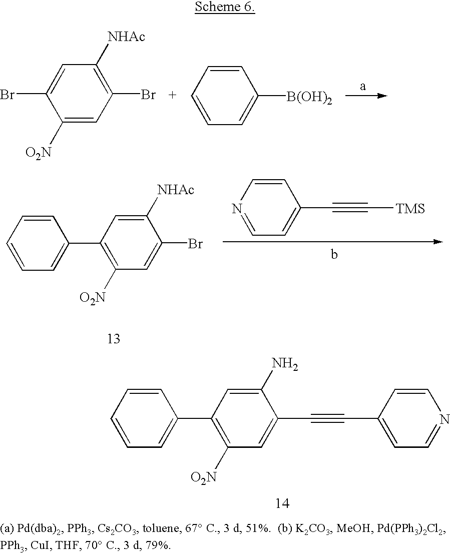

In conclusion, the synthesis of conjugated aromatic molecules containing pyridine units for molecular electronics was accomplished using palladium-catalyzed couplings.

### Example 3

Negative Differential Resistance

Referring again to FIG. 3, negative differential resistance was observed in exemplary molecular diodes 30, in particular a molecular a mono-nitro substituted oligophenylene 32, in particular 4,4′-diphenyleneethynelene-2′-nitro-1-benzenethiol and a di-nitro substituted oligophenylene 34, in particular 2′,5′-dinintro-4,4′-diphenyleneethynylene-1-benzenethiol.

Referring now to FIGS. 4A and 4B, the I(V) response curves of the molecules shown in FIG. 2 (where I denotes current and V denotes voltage) are shown. These curves were obtained by measuring the response of a self-assembled monolayer of molecules 32 and molecules 34. In each monolayer the molecules were oriented with the thiol substituted ends contacting a gold lead and the unsubstituted opposite ends contacting a second gold lead.

Referring now in particular to FIG. 4A, for molecule 32, initially the I(V) response is in the “0” state (open circles). Once application of a 1.75V pulse takes place, the molecule sets into a new state, “1” (black circles), that exhibits negative differential resistance (NDR) behavior, where the current rises then falls with increased voltage.

Referring now in particular to FIG. 4B, for molecule 34, initially the I(V) response is in a “1” state (closed circles), that exhibits NDR. Once application of a 1.5 V pulse takes place, the molecule sets into a new state, “0” (open circles). The initial state is restored by application of a negative bias. This is the reverse of the initial/final switching observed for molecule 32, as shown in FIG. 3A. However, each behavior is exemplary of the duality of switch states. An advantage of molecule 34 is that it is a molecule that exhibits negative differential resistance at room temperature. Further, the retention of the switched state was observed for 24 h. It is believed that longer retention times will be possible with improved packaging of the system. It is preferred that a nanocell 12 is hermetically sealed to improve stability of the switched states for longer times.

The NDR curve shown in FIG. 4B was used for the dynamic nanocell simulations and the SPICE simulations described below.

### Example 4

It has been discovered by the present inventors that simulated nanocells that are based on nano-networks containing arrayed molecular switches connected by nanoparticles are trainable to act as exemplary known logic devices. The molecular switches are molecules that exhibit an I(V) response that is characterized by negative differential resistance

It is believed that the simulated nanocells are representative of actual physical nanocells. Hence, it is believed that, for the first time, a technique for programming an actual nanocell has been discovered. The inventors are aware of no other demonstration of the learning of logic by a network that includes “dendrites” (using the conventional analogy to the structure of the brain) that have these I(V) characteristics. In particular, conventional neural network models of the brain and other simulated systems usually are based on representations of systems that have “dendrite” I(V) curves selected from among step functions, hyperbolic tangents, and the like, none of which have negative differential resistance.

A genetic algorithm was used to train simulated nanocells omnisciently. That is, the algorithm knew the states of remote molecular switches. The algorithm trained the nanocells by omnipotent switching, that is by adjusting the states of the switches directly. It is nonetheless believed that these results are representative of results that are achievable by self-adaptive algorithms that mortally configure remote molecular switches by adjusting voltages at input and output leads.

General Programmning

The object in programming or training a nanocell is to take a random, fixed nanocell and turn its switches “on” and “off” until it functions as a target logic device. The physical position of each molecular switch is first fixed; i.e. the internal topology of the nanocell is static. The nanocell is then trained post-fabrication. Only the states, “on” or “off”, of the molecular switches can change.

Here we introduce the terms omniscience, omnipotence and mortal switching in relation to the programming algorithms used. By omniscience we mean that the connections within the nanocell and the location and state of each switch are known. Omnipotence means that the search algorithm knows the location of each molecular switch and has precise and selective access to reversibly set its “on” or “off” state. Naturally, the definition of omnipotence includes omniscience. Finally, with mortal switching, the algorithm does not know the connections within the nanocell or locations of the switches, and switching is limited to voltage pulses applied to the input/output pins. An actual physical nanocell is desirably programmed in a mortal fashion and switching will occur only through voltage pulses between contact pads along the periphery.

In the simulations presented here, we demonstrate that there are switch states such that a given nanocell functions as a target logic device. Given a certain density of nanoparticles and molecular switches, it is desirable to determine whether any random nanocell can be trained as some target logic device, with the assumption of absolute control over switch states. Some preliminary strategies for extending the method to mortal switching include taking advantage of the capacitances of the gold particles to better access individual switches. It is believed that a line of molecular switches between two I/O pins, where there is exactly one switch and some capacitance between two gold particles, can be set to any pattern of “on” and “off” states by using these capacitances. The network of molecular switches and gold particles within a nanocell is much more complicated than a simple line of switches between I/O pins; however, simulations indicate that the solution space for some logic gates is quite dense. This implies that it will not be necessary to uniquely access every individual molecule. In fact, if there are multiple switches between two gold particles, then every switch oriented in one direction will switch states simultaneously. However, this should not be a problem because toggling groups of molecules is most likely sufficient.

The nanocell training problem with omnipotence is a combinatorial optimization problem where the search space is the set of all possible switch states for some fixed nanocell. If a nanocell contains 250 nanoparticles and about 750 molecular switches in a suitable orientation for switching, then the size of this search space is 2⁷⁵⁰ (as a size comparison, the number of elemental particles in the universe is estimated at 2³⁰⁰). A genetic algorithm is used to search this space. First a random nanocell is generated and a target logic device is defined (such as NAND). The states of the nanocell's switches are stored as a “chromosome” of “1's” and “0's”. An initial generation of random chromosomes is produced. Each chromosome corresponds to a different set of switch states for the nanocell with fixed locations of nanoparticles and molecular switches. A fitness function is formulated such that switch states that cause the nanocell to perform as the target logic device receive low scores while those that do not perform the target logic function receive high scores. The search stops when a chromosome of switch states obtains a score of zero, and thus acceptably performs the desired logic. After the first generation, each generation of new chromosomes is produced by operations performed on the previous generation. Highly fit, or low-scoring, chromosomes combine in pairs to form new and hopefully even better performing chromosomes. In this manner, the space is searched until a chromosome of fitness zero is obtained.

Here we present two methods of simulating this omnipotent training process. In order to calculate the fitness of each configuration, or combination of switch states within a nanocell, a series of circuits must be analyzed. Each of these circuits contains a complex network of nonlinear resistors. A pattern of input voltages over time is applied to some of the input/output pins, and the resulting output current over time must be calculated. This involves solving a series of nonlinear, ordinary differential equations. Though solving this system is difficult, the simulations presented here address this in two ways. In the model that we present second, the circuit engineering software, SPICE, is used to analyze each configuration of the nanocell. This software is highly accurate but time consuming, as it is not designed to run iterations of randomly assembled circuits. In the dynamic nanocell model that we present first, the accuracy is sacrificed for the sake of speed; the electrical behavior of the nanocell is approximated so that the complex system of equations is not solved, but a useful approximation can be obtained.

The genetic algorithm used is recorded on the attached CD-ROM in file nanocell.cpp in the subdirectory Spice Nanocell Simulator.

Dynamic Nanocell Model

Cellular automata (CA) are dynamical system with discrete values for space and time. The states of cells in a regular lattice are updated synchronously according to a deterministic rule relying only on the states of local or neighboring cells [c]. While the state of each cell is often limited to small set of discrete values, it is not uncommon to extend the concept of CA's to permit a real valued state variable [d]. The dynamic nanocell model is a cellular automata in which a hexagonal lattice represents the nanocell and the cells in the lattice represent individual gold nanoparticles. The real valued state variable for a cell is the voltage potential of the nanoparticle and the transition rule for changing the state variable at each time step is to adjust the voltage potential of the nanoparticle to make it Kirchhoff compliant with its neighboring cells. It has been said that computer scientist use cellular automata where physicist's use field theory governed by “field equations” and that using CA's provides an alternative computational approach that may outperform conventional methods by many orders of magnitude [a][b]. We believe that the dynamic nanocell model allows our search algorithms to execute in a timely manner and still accurately model the electrical characteristics of a physical device.

The transition rule for the dynamic nanocell model took into account the nonlinearity of the I(V) curve in the NDR devices and allowed the model to simulate electric flow passing through the nanocell, not just fluid flow. This provided the capability to model more interesting logical devices, such as those with negating logic.

The dynamic model was evaluated in an incremental fashion as follows. All of the metallic nanoparticles were initialized with a voltage potential of 0, then a non-zero potential was applied to some of the nanoparticles that have been designated as input/output points. The voltage potentials applied to the input points were ramped up incrementally until they reach the levels that represent the Boolean valued input to the nanocell and were then held constant through the simulation. The effected nanoparticles signaled their neighbors that a change has occurred. The nanoparticles then re-evaluated their own potentials by comparing their voltage potential with that of each of their immediate neighbors. The voltage differential of each neighbor along with the I(V) characteristics of the intervening molecular switches determined the amount of current that passes to or from each neighbor. If the sum of the current entering from some neighbors was not equal to the sum of the current that flows out to the remaining neighbors, then the nanoparticle's voltage potential was adjusted accordingly. If an adjustment was performed, then neighboring nanoparticles were signaled to re-evaluate their potentials. This process was continued until nanoparticles were satisfied that their entering current were equal to their exiting current, thereby making the system Kirchhoff-compliant. Finally, the current was calculated at each input/output.

Genetic algorithms were used to find a combination of switch settings that make the nanocell behave as a desired logic gate. Since switches were either in an “on” or an “off” state, the chromosome model was a set of bits, at values of 0 or 1, representing the state of all the switches in the cell, “off” or “on”, respectively. Hexagonal arrays were used. That is, the nanoparticles were laid down at the corners of triangles, with switches along the sides of the triangles. The genetic algorithm was able to find a combination of switch settings to make a small, 4×4, nanocell act as an XOR device. Further, it has been demonstrated in a “circular” nanocell with a radius of one (that is one central nanoparticle surrounded by an approximately circular perimeter of six nanoparticles) that the nanocell can be trained to function as any of the 8 2×1 truth tables (2 inputs, 1 output). Still further, it has been demonstrated in a “circular” nanocell with a radius of two (the above radius-one nanocell surrounded by another approximately circular perimeter of 12 nanoparticles) any of the 64 2×2 truth tables (2 inputs, 2 outputs). This dynamic nanocell model is simple and it executes relatively quickly making it an excellent tool for studying search techniques and logical properties of the nanocell.

Each of the following references is hereby incorporated herein by reference:

[a] T. Toffoli, N. H. Margolus; “Invertible Cellular Automata: A Review”, Cellular Automata: Theory and Experiment, H. Gutowitz, editor; 1991, A Bradford Book, The MIT Press, Cambridge, Mass., London England.

[b] T. Toffoli; “Cellular Automata as an Alternative to (Rather than An Approximation of) Differential Equations in Modeling Physics. PHYSICA D, Nonlinear Phenomena, Vol 10D (1984) Nos. 1 & 2, January 1984

[c] H. Gutowitz; “Introduction”, Cellular Automata: Theory and Experiment, H. Gutowitz same as [a]

[d] Chopard, Droz; Cellular Automata Modeling of Physical Systems; 1998, Cambridge University Press

SPICE Model

Spice Model

The SPICE model simulates the complex device circuit properties of a nanocell. We configured SPICE to interface with the genetic algorithm described in the previous section. Using Microsoft's COM platform to interface through OLE to Intusoft's ICAPS/4 Windows SPICE variant, a nanocell simulator was developed. Calculations were also performed with HSPICE v. 1999.2 available from Avant. The nanocell simulator randomly generates nanocells and configures them to function as simple logic gates. Given the density and dimensions of the nanoparticles and the average density of the molecular switches, a random nanocell is generated as a hexagonal grid of metallic particles with the specified chosen density. Molecular switches connecting adjacent nanoparticles are distributed following a Poisson distribution based around the given average density (FIG. 7). After the creation of a nanocell, the settings on 20 surrounding input/output pins (five pins occupying each of the four sides) are specified. Each input/output pin can be set to input, output, or to float and thus behave like a nanoparticle. Inside the SPICE engine, individual molecules are modeled using nonlinear resistor circuit elements. Achieving convergence in SPICE was resolved by including the parasitic capacitance expected between the nanoparticles. The added capacitance prevents abrupt changes in the current from occurring during simulations, which more realistically models the nanocell architecture and helps with convergence.

In the work described here, the logic gates are voltage-input and current-output circuits. When setting the input/output pins to “high” or “low”, we let V_{IL} and V_{IH} be the low and high voltages for input pins, respectively. When the truth table value of an input is 1, V_{IH} volts are applied to this pin. A truth table value of 0 indicates that V_{IL} volts are applied. Similarly, we set I_{OL} and I_{OH} as the output current thresholds, respectively. If the current through an output pin is at or below I_{OL}, that pin is considered “off”, and if the current is at or above I_{OH}, the pin is considered “on”.

Given a number of two-state inputs and outputs, a truth table describes the desired logic. Testing each individual truth is not sufficient. Each transition between truths must be tested as well. Input graphs and corresponding truth tables for an inverter, a NAND gate, and the inverse of a half-adder are displayed in a later section.

By parsing the output from SPICE, we determined the output of the nanocell at each clock step. We then compare these readings to I_{OH} and I_{OL} to determine if the output pin is “on”, “off”, or neither (between the discrete threshold settings). In this way, we determined the logic of any given nanocell. By comparing this logic to the desired truth table, we can determine if the nanocell performs the desired logic function.

For a fixed nanocell it is desirable to search among all possible combinations of switch states, where the location of each switch is fixed. In other words, a new switch cannot be added between nanoparticles, and existing switches cannot be removed. Only the switch states can be altered. In the SPICE model, pin settings and “on” and “off” current thresholds (I_{OL} and I_{OH}) were constant. The objective was to fix these parameters such that any random nanocell, of a particular nanoparticle and molecular switch density, can be trained as some target logic gate. Exemplary setting were determined for inverters, NAND gates and inverse half-adders.

A representative SPICE listing of an exemplary nanocell in an unprogrammed state is recorded on the attached CD-ROM in file Trained Nanocell.doc. The “on”-“off” states of the molecular switches of the unprogrammed nanocell is shown in FIG. 7.

A representative SPICE listing a the same nanocell reprogrammed to function as an Inverter is recording on the attached CD-ROM in file Trained Nanocell.doc. The “on”-“off” states of the nanocell functioning as a programmed Inverter are shown in FIG. 8.

A representative SPICE listing of the same nanocell programmed to function as a NAND gate is recorded on the attached CD-ROM in file Trained Nanocell.doc. The “on”-“off” states of the nanocell functioning as a programmed NAND are shown in FIG. 9.

A representative SPICE listing of the same nanocell programmed to function as a Inverse Half Adder is recorded on the attached CD-ROM in file Trained Nanocell.doc. The “on”-“off” states of the nanocell functioning as a programmed Inverse Half Adder are shown in FIG. 10.

The above-described results demonstrate the programmable and reprogrammability of the exemplary nanocell shown in FIG. 7.

While preferred embodiments of this invention have been shown and described, modifications thereof can be made by one skilled in the art without departing from the spirit or teaching of this invention. The embodiments described herein are exemplary only and are not limiting. Many variations and modifications of the device, computer, and methods are possible and are within the scope of the invention. Accordingly, the scope of protection is not limited to the embodiments described herein, but is only limited by the claims that follow, the scope of which shall include all equivalents of the subject matter of the claims.

We claim:

1. A programmable molecular device, comprising:
at least one input lead;
at least one output lead; and
a nano-network spanning said input lead and said output lead, wherein said nano-network comprises a plurality of molecular circuit components.

2. The programmable molecular device according to claim 1 wherein said nano-network is self-assembled.

3. The programmable molecular device according to claim 1 wherein said nano-network is random.

4. The programmable molecular device according to claim 1 wherein said device is programmable by a self-adaptive algorithm for configuring said molecular circuit components.

5. The programmable molecular device according to claim 4 wherein said self-adaptive algorithm is selected from the group consisting of genetic algorithms, simulated annealing algorithms, go with the winner algorithms, temporal difference learning algorithms, reinforcement learning algorithms, and combinations thereof.

6. The programmable molecular device according to claim 4 wherein said molecular circuit components are configurable by applying a voltage across said input lead and said output lead.

7. The programmable molecular device according to claim 1 wherein said device is programmable to function as a logic unit.

8. The programmable molecular device according to claim 7 wherein said logic unit is selected from the group consisting of truth tables supported by said at least one input lead and said at least one output lead.

9. The programmable molecular device according to claim 8 wherein said logic unit is programmable to function as a device selected from the group consisting of an AND, an OR, an XOR, a NAND, a NOT, an Adder, a Half-adder, an Inverse Half-Adder, a Multiplexor, and a Decoder, and combinations thereof.

10. The programmable molecular device according to claim 1 wherein said device is programmable to function as a memory unit.

11. The programmable molecular device according to claim 1 wherein said device is reprogrammable.

12. The programmable molecular device according to claim 1 wherein said molecular circuit components are selected from the group consisting of molecular switches, molecular diodes, molecular wires, molecular rectifiers, resistors, transistors, molecular memory, and combinations thereof.

13. The programmable molecular device according to claim 12 wherein said molecular circuit components comprise molecular switches.

14. The programmable molecular device according to claim 13 wherein said device is programmable by an algorithm for setting said molecular switches.

15. The programmable molecular device according to claim 14 wherein said switches are settable by applying a voltage across said input lead and said output lead.

16. The programmable molecular device according to claim 1 wherein said nano-network further comprises nanoscale components.

17. The programmable molecular device according to claim 16 wherein said nanoscale components are selected from the group consisting of nanotubes, nanoparticles, nanorods, and combinations thereof.

18. The programmable molecular device according to claim 17 wherein said nanoscale circuit components comprise nanoparticles and said molecular circuit components comprise molecular switches and said molecular switches interconnect said nanoparticles.

19. The programmable molecular device according to claim 18 wherein said nanoparticles are randomly arrayed.

20. The programmable molecular device according to claim 18 wherein said molecular switches randomly interconnect said nanoparticles.

21. A method of making an electronic component, comprising:
(a) providing a self-assembled nanocell; and
(b) programming the nanocell to function as the electronic component.

22. The method according to claim 21 wherein the nanocell comprises:
at least one input lead;
at least one output lead; and
a nano-network spanning the input lead and the output lead, wherein the nano-network comprises a plurality of molecular circuit components.

23. The method according to claim 22 wherein the molecular circuit components are selected from the group consisting of molecular switches, molecular diodes, molecular wires, molecular rectifiers, molecular resistors, molecular transistors, molecular memories and combinations thereof.

24. The method according to claim 23 wherein the molecular circuit components comprises molecular resonant tunneling diodes.

25. The method according to claim 24 wherein the molecular circuit components exhibit negative differential resistance.

26. The method according to claim 22 wherein the nano-network further comprises nanoscale components selected from the group consisting of nanotubes, nanoparticles, nanorods, and combinations thereof.

27. The method according to claim 22 wherein said nano-network is random.

28. The method according to claim 21 wherein step (b) comprises:
(b1) configuring the molecular circuit components.

29. The method according to claim 28 wherein step (b1) comprises:
(b1.i) adjusting a conductivity-affecting property of at least one of the molecular circuit components by applying a voltage across the input lead and the output lead.

30. The method according to claim 29 wherein the conductivity-affecting property is selected from the group consisting of charge, conformational state, electronic state, and combinations thereof.

31. The method according to claim 28 wherein step (b) further comprises:
(b2) testing the performance of the nanocell.

32. The method according to claim 31 wherein step (b) further comprises:
(b3) applying a self-adaptive algorithm to reconfigure the molecular circuit components.

33. The method according to claim 32 wherein the self-adaptive algorithm is selected from the group consisting of genetic algorithms, simulated annealing algorithms, go with the winner algorithms, temporal difference learning learning algorithms, reinforcement learning algorithms, and combinations thereof.

34. The method according to claim 32 further comprising:
(b4) repeating steps (b2) and (b3) until the nanocell functions as the electronic component.

35. The method according to claim 22 wherein the electronic component comprises a logic unit.

36. The method according to claim 35 wherein the logic unit is selected from the group consisting of truth tables supported by the input leads and output leads.

37. The method according to claim 36 wherein the logic unit is selected from the group consisting of an AND, an OR, an XOR, a NOR, an NAND, a NOT, an Adder, a Half-Adder, an Inverse Half-Adder a Multiplexor, a Decoder, and combinations thereof.

38. The method according to claim 22 wherein the electronic component comprises a memory unit.

39. The method according to claim 22 wherein step (a) comprises:
(a1) allowing a plurality of nanoscale components to self-assemble into a random array;
(a2) allowing the plurality of molecular circuit components to self-assemble into a random molecular interconnect between the nanoscale components; and
(a3) bonding the molecular circuit components to the nanoscale components with molecular alligator clips.

40. The method according to claim 39 wherein the molecular alligator clips are selected from the group consisting of sulfur, oxygen, selenium, phosphorous, isonitrile, pyidine, carboxylate, and thiol moieties.

41. The method according to claim 39 wherein the nanoscale components are selected from the group consisting of nanotubes, nanoparticles, nanorods, and combinations thereof.

42. The method according to claim 39 wherein the molecular circuit components are selected from the group consisting of molecular switches, molecular diodes, molecular wires, molecular rectifiers, molecular resistors, molecular transistors and combinations thereof.

43. A molecular computer, comprising:
a plurality of programmable nanocells, each nanocell comprising:
a plurality of nanoparticles; and
a plurality of molecular diodes;
wherein said molecular diodes interconnect said nanoparticles; and
a plurality of metallic wires;
wherein said metallic wires interconnect said nanocells.

44. The molecular computer according to claim 43 wherein said nanocell is self-assembled.

45. The molecular computer according to claim 43 wherein said nanoparticles are randomly arrayed.

46. The molecular computer according to claim 43 wherein said molecular diodes randomly interconnect said nanoparticles.

47. The molecular computer according to claim 43 wherein each said nanocell comprises a linear dimension of up to about 2 microns.

48. The molecular computer according to claim 43 wherein at least one of said nanocells is programmable to function as a logic unit.

49. The molecular computer according to claim 48 wherein said logic unit is selected from the group consisting of truth tables supported by the wire interconnection.

50. The method according to claim 49 wherein at least one of said nanocells is programmable to function as a device selected from the group consisting of AND, OR, XOR, NOR, NAND, NOT, an Adder, a Half Adder, an Inverse Half Adder, a Multiplexor, a Decoder, and combinations thereof.

51. The molecular computer according to claim 43 wherein at least one of said nanocells is programmable to function as a memory unit.

52. The molecular computer according to claim 43 wherein said nanocell is programmable by an algorithm for configuring said nanocell's molecular diodes.

53. The molecular computer according to claim 43 wherein said said nanocell further comprises:
first and second leads; and
wherein said diodes are configurable by applying a voltage to said first and second leads.

54. The molecular computer according to claim 43 wherein at least one of said molecular diode exhibits negative differential resistance.

55. A method of making a computer, comprising:
(a) providing a plurality of trained self-assembled nanocells;
(b) interconnecting said trained nanocells to a plurality of untrained nanocells;
(c) allowing the trained nanocells to train the untrained nanocells.

56. The method according to claim 53, further comprising:
(d) hierarchically repeating steps (b) and (c).
